(19) United States
(12) Patent Application Publication
(10) Pub. No.: US 2026/0020489 A1
(43) Pub. Date: Jan. 15, 2026

(54) DISPLAY DEVICE AND ELECTRONIC DEVICE

(71) Applicant: Samsung Display Co., Ltd., Yongin-si (KR)

(72) Inventors: KWANG-MIN LEE, Yongin-si (KR); KANGUK KIM, Yongin-si (KR); CHEHO LIM, Yongin-si (KR); KANG SOO HAN, Yongin-si (KR)

(21) Appl. No.: 19/232,725

(22) Filed: Jun. 9, 2025

(30) Foreign Application Priority Data
Jul. 12, 2024 (KR) 10-2024-0092609

(51) Int. Cl. H10K 59/80; H10K 59/122; H10K 59/38

(52) U.S. Cl. CPC H10K 59/8792; H10K 59/122; H10K 59/38

(57) ABSTRACT

A display device is provided. The display device includes a display panel including a display area and a peripheral area adjacent to the display area, a light control layer on the display panel and including a plurality of light control parts and a bank layer between the plurality of light control parts, and a color filter layer on the light control layers and including a filter part in which a single color filter is arranged, and a blocking part in which at least two or more color filters overlap. The bank layer includes a first bank layer on the display area and on a first blocking part of the blocking part, where three color filters overlap in the first blocking part, and a second bank layer on the peripheral area and on a second blocking part of the blocking part, where two color filters overlap in the second blocking part.

### CROSS-REFERENCE TO RELATED APPLICATIONS

The present application claims priority to and the benefit of Korean Patent Application No. 10-2024-0092609, filed on Jul. 12, 2024, the entire content of which is hereby incorporated by reference.

### BACKGROUND

### 1. Field

Embodiments of the present disclosure relate to a display device, and for example, to a display device having enhanced (improved) reliability.

### 2. Description of the Related Art

Multimedia display devices, such as televisions, mobile phones, tablets, computers, navigation systems, game consoles, and/or the like, may include (be provided with) display panels for displaying images. The display panel may include a plurality of pixels for displaying an image, and each of the pixels may include a light-emitting element that generates light and a driving element connected to the light-emitting element.

Recently, display devices including (incorporating) a light conversion layer are being developed to enhance (improve) visibility and color purity. These display devices are manufactured by bonding a substrate with a light-emitting element to a substrate with a light conversion layer. However, defects may occur during the process of bonding the substrates of the display device together, necessitating or desiring further research to address these issues.

### SUMMARY

Aspects of one or more embodiments of the present disclosure are directed toward a display device with (having) enhanced (improved) display quality.

Additional aspects will be set forth in part in the description which follows and, in part, will be apparent from the description, or may be learned by practice of the presented embodiments of the disclosure.

In one or more embodiments of the present disclosure, a display device includes: a display panel including a display area and a peripheral area adjacent to the display area; a light control layer arranged on the display panel and including a plurality of light control parts and a bank layer that divides (e.g., between) the plurality of light control parts; and a color filter layer arranged on the light control layers and including a filter part on (in) which a single color filter is arranged, and a blocking part in which at least two or more color filters overlap. The bank layer includes: a first bank layer arranged on the display area and arranged on a first blocking part of the blocking part, where three color filters overlap in the first blocking part; and a second bank layer arranged on the peripheral area and arranged on a second blocking part of the blocking part, where two color filters overlap in the second blocking part. For example, in one or more embodiments of the present disclosure, a display device includes: a display panel with a display area and a peripheral area adjacent to the display area; a light control layer arranged on the display panel, including a plurality of light control parts and a bank layer that divides the plurality of light control parts; and a color filter layer arranged on the light control layer, including a filter part, on which a single color filter is arranged, and blocking parts, in (e.g., each or at least one) which at least two or more color filters overlap. The bank layer includes: a first bank layer arranged on the display area and on a first blocking part of the blocking parts, where three color filters overlap; and a second bank layer arranged on the peripheral area and on a second blocking part of the blocking parts, where two color filters overlap.

In one or more embodiments of the present disclosure, a display device includes: a display panel including a display area and a peripheral area adjacent to the display area; a color filter layer including a filter part in which a single color filter is arranged and a blocking part in which at least two or more color filters overlap; and a light control layer arranged between the display panel and the color filter layer and including a plurality of light control parts and a bank layer that divides (e.g., between) the plurality of light control parts. The bank layer includes: a first bank layer arranged on the display area and a second bank layer arranged on the peripheral area. A sum of a height (e.g., thickness) of the first bank layer and a height (e.g., thickness) of the blocking part is less than that of a height (e.g., thickness) of the second bank layer and a height (e.g., thickness) of the blocking part.

In one or more embodiments of the present disclosure, an electronic device includes a display device, an electronic module overlapping the display device and a housing accommodating the display device. The display device includes a display panel including a display area and a peripheral area adjacent to the display area; a light control layer arranged on the display panel and including a plurality of light control parts and a bank layer that divides (e.g., between) the plurality of light control parts; and a color filter layer arranged on the light control layers and including a filter part in which a single color filter is arranged, and a blocking part in which at least two or more color filters overlap. The bank layer may include: a first bank layer arranged on the display area and arranged on a first blocking part of the blocking part, where three color filters overlap in the first blocking part; and a second bank layer arranged on the peripheral area and arranged on a second blocking part of the blocking part, where two color filters overlap in the second blocking part.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a perspective view of a display device according to one or more embodiments of the present disclosure;

FIG. 2 is an exploded perspective view illustrating the display device of FIG. 1, according to one or more embodiments of the present disclosure;

FIG. 3 is a cross-sectional view of a display module according to one or more embodiments of the present disclosure;

FIG. 4 is a plan view of a display panel according to one or more embodiments of the present disclosure;

FIG. 5 is an enlarged view of an area AA′ of FIG. 4, according to one or more embodiments of the present disclosure;

FIG. 6 is a cross-sectional view of the display panel according to one or more embodiments of the present disclosure;

FIG. 7 is a cross-sectional view of the display module taken along the line II-II′ of FIG. 5, according to one or more embodiments of the present disclosure;

FIG. 8 is a cross-sectional view of the display module taken along the line I-I′ of FIG. 2, according to one or more embodiments of the present disclosure;

FIG. 9A is an enlarged view of an area BB′ of FIG. 8, according to one or more embodiments of the present disclosure;

FIG. 9B is an enlarged view of an area CC′ of FIG. 8, according to one or more embodiments of the present disclosure;

FIGS. 10A and 10B are each a cross-sectional view of a display module taken along the line I-I′ of FIG. 2, according to embodiments of the present disclosure;

FIGS. 11A-11F are each a cross-sectional view of a display module taken along the line I-I′ of FIG. 2, according to embodiments of the present disclosure; and

FIGS. 12A and 12B are cross-sectional views for explaining a method of manufacturing first and second bank layers of FIG. 8, according to one or more embodiments of the present disclosure.

FIG. 13 is a perspective view of an electronic device according to one or more embodiments of the present disclosure.

FIG. 14 is a perspective view illustrating a folded state of the electronic device illustrated in FIG. 13, according to one or more embodiments of the present disclosure.

FIG. 15 is an exploded perspective view of the electronic device illustrated in FIG. 13, according to one or more embodiments of the present disclosure.

FIG. 16 is a block diagram of the electronic device illustrated in FIG. 13, according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, duplicative descriptions thereof may not be provided. In the drawings, the relative sizes of elements, layers, and regions may be exaggerated for clarity.

As used herein, the term “and/or” includes any and all combinations of one or more of the associated listed items.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an” and “the” are intended to include the plural forms as well, unless the context clearly indicates otherwise.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Unless otherwise defined, all terms (including technical and scientific terms) used herein have the same meaning as commonly understood by a person of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

In the context of the present disclosure and unless otherwise defined, a plan view is an orthographic projection of a three-dimensional object from the position of a horizontal plane through the object. That is, it is a top-down view, showing the layout and spatial relationships of various elements within the object or structure. A plan view based on the direction DR3 refers to a top-down view of the display panel, as if looking directly down onto the surface from above. In this context, DR3 is the direction perpendicular or normal to the plane defined by the first direction DR1 and the second direction DR2. This refers to that in a plan view, the arrangement of sub-pixels, pads, and other components as they are laid out on the substrate can be seen, without any perspective distortion.

Hereinafter, example embodiments of the present disclosure will be described with reference to the accompanying drawings.

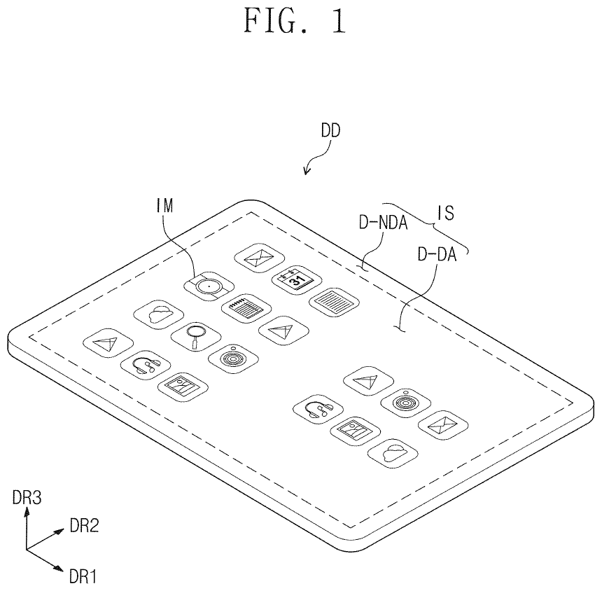

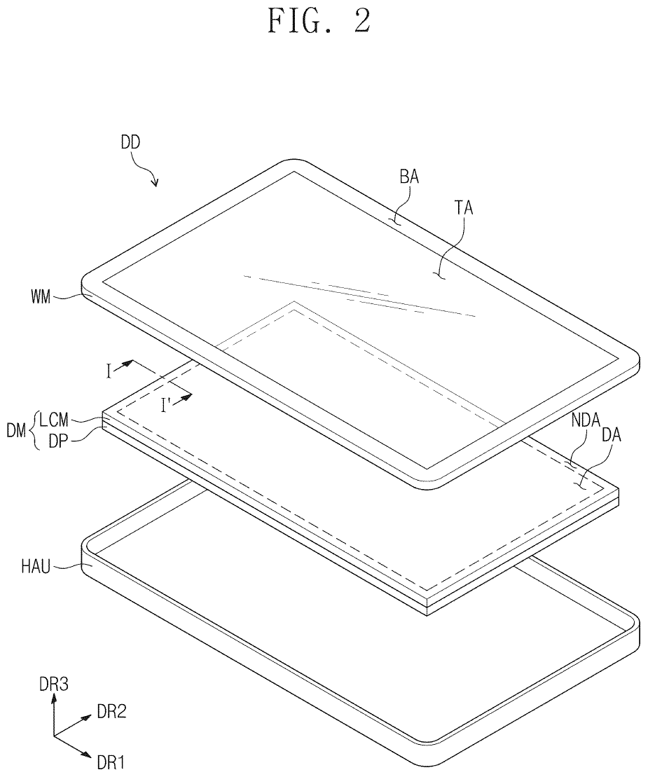

FIG. 1 is a perspective view of a display device according to one or more embodiments of the present disclosure. FIG. 2 is an exploded perspective view illustrating the display device of FIG. 2 according to one or more embodiments of the present disclosure.

A display device DD may be a device that is activated by an electrical signal and displays an image. The display device DD may include one or more suitable embodiments in which an image is provided to a user, and for example, the display device DD may be a large device such as a television, an outdoor billboard, and/or the like, as well as a small or medium-sized device such as a monitor, a mobile phone, a tablet computer, a navigation system, a game console, and/or the like. The embodiments of the display device DD are only examples and the present disclosure is not limited thereto.

Referring to FIG. 1, the display device DD may have a rectangular shape having long sides extending in a first direction DR1 and short sides extending in a second direction DR2 intersecting the first direction DR1 on a plane (e.g., in a plan view). However, the present disclosure is not limited thereto, and the display device DD may have one or more suitable shapes such as circular and/or polygonal shapes.

Hereinafter, a direction substantially perpendicularly crossing a plane defined by the first direction DR1 and the second direction DR2 may be defined as a third direction DR3. In this specification “when viewed on the plane” or “in a plan view” may be defined in a state when viewed in the third direction DR3. In this specification, “in a cross-section” or “in a cross-sectional view”) may be defined in a state when viewed in the first direction DR1 or the second direction DR2.

The display device DD may display an image IM in the third direction DR3 through a display surface IS parallel to a plane defined by the first direction DR1 and the second direction DR2. The third direction DR3 may be substantially parallel to a normal (e.g., perpendicular) direction of the display surface IS. The display surface IS on which the image IM is displayed may correspond to a front surface of the display device DD. The image IM may include a still image as well as a dynamic image. FIG. 1 illustrates icon images as an example of the image IM.

In one or more embodiments, a front surface (or top surface) and a rear surface (or bottom surface) of each member or unit may be defined based on the direction in which the image IM is displayed. The front and rear surfaces may be opposite to each other in the third direction DR3. A normal (e.g., perpendicular) direction of each of the front and rear surfaces may be parallel to the third direction DR3. A spaced distance between the front and rear surfaces defined along the third direction DR3 may correspond to a thickness of the member (or unit).

FIG. 1 illustrates an example of a display device DD having a planar display surface IS. However, the shape of the display surface IS of the display device DD is not limited thereto, and the display surface IS may have a curved or three-dimensional shape.

The display device DD may be flexible. Being “flexible” refers to a bendable property and may include a structure that is completely folded and a structure that is folded to have a few nanometer of separation or space between the folded sides. For example, the flexible display device DD may be a curved device or a foldable device. However, the present disclosure is not limited thereto, and the display device DD may be rigid.

The display surface IS of the display device DD may include a display part D-DA and a non-display part D-NDA. The display part D-DA may be a portion, on which the image IM is displayed, within the front surface of the display device DD, and thus, a user may recognize the image IM through the display part D-DA. Although FIG. 1 illustrates a display part D-DA having a rectangular shape as an example, the display part D-DA may have one or more suitable shapes depending on its design.

The non-display area D-NDA may be a portion, on which the image IM is not displayed, within the front surface of the display device DD. The non-display area D-NDA may be a portion that has a set or predetermined color and blocks light. The non-display part D-NDA may be adjacent to the display part D-DA. For example, the non-display part D-NDA may be arranged outside the display part D-DA to be around (e.g., surround) the display part D-DA. However, this embodiment is only an example, and the non-display part D-NDA may be adjacent to only one side of the display part D-DA or may be arranged on a side surface other than the front surface of the display device DD However, the present disclosure is not limited thereto, and in one or more embodiments, the non-display part D-NDA may not be provided.

The display device DD according to one or more embodiments may sense an external input applied from the outside. An external input may include one or more suitable types (kinds) of input, such as a pressure, a temperature, light, and/or the like, provided from the outside. The external input may include an input that is in contact with the display device DD (e.g., contact by user's hand or a pen), as well as an input that is applied in proximity to the display device DD (e.g., hovering).

Referring to FIG. 2, the display device DD may include a window WM, a display module DM, and an outer case HAU. The display module DM may include a display panel DP and a light control member LCM arranged on the display panel DP.

The window WM and the outer case HAU may be coupled to define an outer appearance of the display device DD and provide an internal space that accommodates components of the display device DD such as the display module DM.

The window WM may be arranged on the display module DM. The window WM may protect the display module DM against an external impact. The front surface of the window WM may correspond to the display surface IS of the above-described display device DD. The front surface of the window WM may include a transmission area TA and a bezel area BA.

The transmission area TA of the window WM may be an optically transparent area. The window WM may be to transmit an image provided by the display module DM through the transmission area TA, and the user may visually recognize the image. The transmission area TA may correspond to the display part D-DA (see, e.g., FIG. 1) of the display device DD. In this specification, when it states that an area or portion corresponds to another area or portion, or it states that the areas or portions correspond to each other, it refers to the areas or portions overlapping each other, but the areas or portions are not limited to having the same area and/or the same shape.

The window WM may include an optically transparent insulation material. For example, the window WM may include glass, sapphire, or plastic. The window WM may have a single-layered or multi-layered structure. The window WM may further include functional layers such as an anti-fingerprint layer, a phase control layer, and a hard coating layer, which are arranged on the optically transparent substrate.

The bezel area BA of the window WM may be provided as an area on which a material having a set or predetermined color is deposited, applied, or printed on the transparent substrate. The bezel area BA of the window WM may prevent or reduce the likelihood of a configuration of the display module DM that is arranged to overlap the bezel area BA from being visually recognized to the outside. In other words, the bezel area BA may hide the internal structures of the display module DM and prevent them from being visible from the outside. The bezel area BA may correspond to the non-display area D-NDA (see, e.g., FIG. 1) of the display device DD.

The display module DM may be arranged between the window WM and the outer case HAU. The display module DM may display an image according to an electrical signal. The display module DM may include a display area DA and a peripheral area (or non-display area NDA) adjacent to the display area DA.

The display area DA may be an area that is activated according to an electrical signal. The display area DA may be an area that emits an image provided by the display module DM. The display area DA of the display module DM may correspond to the above-described transmission area TA. The image generated on the display area DA may be visually recognized from the outside through the transmission area TA.

The peripheral area NDA may be adjacent to the display area DA. For example, the peripheral area NDA may be around (e.g., surround) the display area DA. However, the present disclosure is not limited thereto, and the peripheral area NDA may have one or more suitable shapes. The peripheral area NDA may be an area on which a driving circuit or driving line for driving elements on the display area DA is arranged, on which one or more suitable signal lines providing electrical signals are arranged, and/or on which pads are arranged. The peripheral area NDA of the display module DM may correspond to the bezel area BA of the window WM, and the configurations of the display module DM arranged on the peripheral area NDA may be prevented from being visually recognized from the outside by the bezel area BA, or the likelihood of being visually recognized from the outside by the bezel area BA may be reduced.

The display panel DP according to one or more embodiments may be an emission-type (kind) display panel, but the present disclosure is not particularly limited thereto. For example, the display panel DP may be an organic light-emitting display panel, an inorganic light-emitting display panel, or a quantum dot light-emitting display panel. An emission layer of the organic light-emitting display panel may include an organic light-emitting material, and an emission layer of the inorganic light-emitting display panel may include an inorganic light-emitting material. An emission layer of the quantum dot light-emitting display panel may include a quantum dot, a quantum rod, and/or the like. Hereinafter, the display panel DP is described as an organic light-emitting display panel according to one or more embodiments.

The light control member LCM may convert a wavelength of light provided from the display panel DP or selectively transmit the light provided from the display panel DP. In one or more embodiments, the light control member LCM may prevent or reduce the likelihood of reflection of external light incident from outside the display device DD.

The outer case HAU may be arranged under the display module DM to accommodate the display module DM. The outer case HAU may be to absorb an impact applied to the display module DM from the outside and prevent or reduce the likelihood of (e.g., protect from) foreign substances, moisture, and/or the like, penetrating into the display module DM in order to protect the display module DM. The outer case HAU according to one or more embodiments may be provided in the form of a plurality of accommodation members that are coupled to each other.

The display device DD may further include an input sensing module, and the input sensing module may acquire coordinate information of an external input applied from outside the display device DD. The input sensing module of the display device DD may be driven in one or more suitable manners such as a capacitive manner, a resistive manner, an infrared manner, and/or a pressure manner, but the present disclosure is not limited thereto.

In one or more embodiments, the input sensing module may be arranged on the display module DM. The input sensing module may be directly arranged on the display module DM through a substantially continuous process, but the present disclosure is not limited thereto. For example, the input sensing module may be manufactured separately from the display module DM and attached to the display module DM by an adhesive layer. In one or more embodiments, the input sensing module may be arranged between the components of the display module DM. For example, the input sensing module may be arranged between the display panel DP and the light control member LCM.

The display device DD may further include an electronic module including one or more suitable functional modules that operate the display module DM, a power supply module that supplies power for the display device DD, a bracket coupled to the display module DM and/or the outer case HAU to divide the internal space of the display device DD.

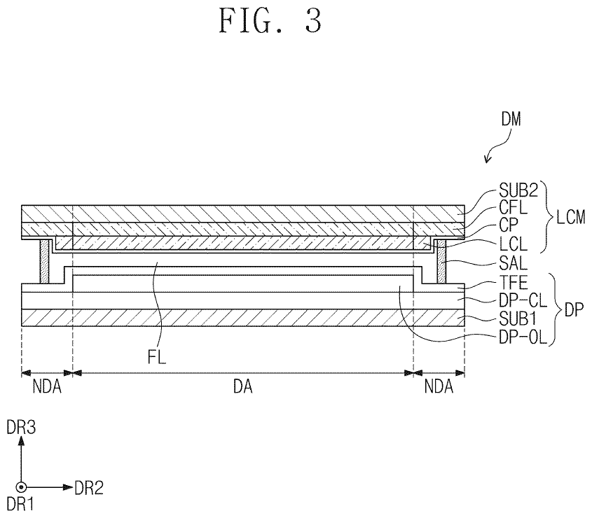

FIG. 3 is a cross-sectional view of the display module according to one or more embodiments of the present disclosure.

Referring to FIG. 3, the display module DM may include the display panel DP, the light control member LCM, a filling member FL, and a sealing member SAL. The description of the display panel DP (or first substrate) and the light control member LCM (or second substrate) may be applied equally to the above description.

For example, the display panel DP may include a first base substrate SUB1 (or lower substrate), a circuit layer DP-CL, a light-emitting element layer DP-OL, and an encapsulation layer TFE.

The first base substrate SUB1 may include a glass substrate, a polymer substrate, and/or an organic/inorganic composite material substrate. The first base substrate SUB1 may include top and bottom surfaces that are parallel to the first direction DR1 and the second direction DR2, respectively. The circuit layer DP-CL, the light-emitting element layer DP-OL, and the encapsulation layer TFE may be sequentially laminated and arranged on a top surface of a first base substrate SUB1 and then may be defined as a first substrate (e.g., the display panel DP).

The light-emitting element layer DP-OL may include light-emitting elements arranged to overlap the display area DA. The circuit layer DP-CL may be arranged between the light-emitting element layer DP-OL and the first base substrate SUB1 and may include driving elements, signal lines, and signal pads connected to the light-emitting elements. The light-emitting elements of the light-emitting element layer DP-OL may provide source light (or first light) toward the light control member LCM within the display area DA.

The encapsulation layer TFE may be arranged on the light-emitting element layer DP-OL to seal the light-emitting elements. The encapsulation layer TFE may include a plurality of thin films. The thin films of the encapsulation layer TFE may be arranged to improve optical efficiency of the light-emitting elements and/or to protect the light-emitting elements.

The light control member LCM may include a second base substrate SUB2 (or upper substrate), a color filter layer CFL, a light control layer LCL, and a capping layer CP.

The second base substrate SUB2 may include a glass substrate, a polymer substrate, and/or an organic/inorganic composite material substrate. The second base substrate SUB2 may include front and rear surfaces that are parallel to the first direction DR1 and the second direction DR2, respectively. The rear surface of the second base substrate SUB2 may face a top surface of the first base substrate SUB1. The color filter layer CFL and the light control layer LCL may be sequentially laminated and arranged on the rear surface of the second base substrate SUB2 and may then be defined as a second substrate (e.g., the light control member LCM).

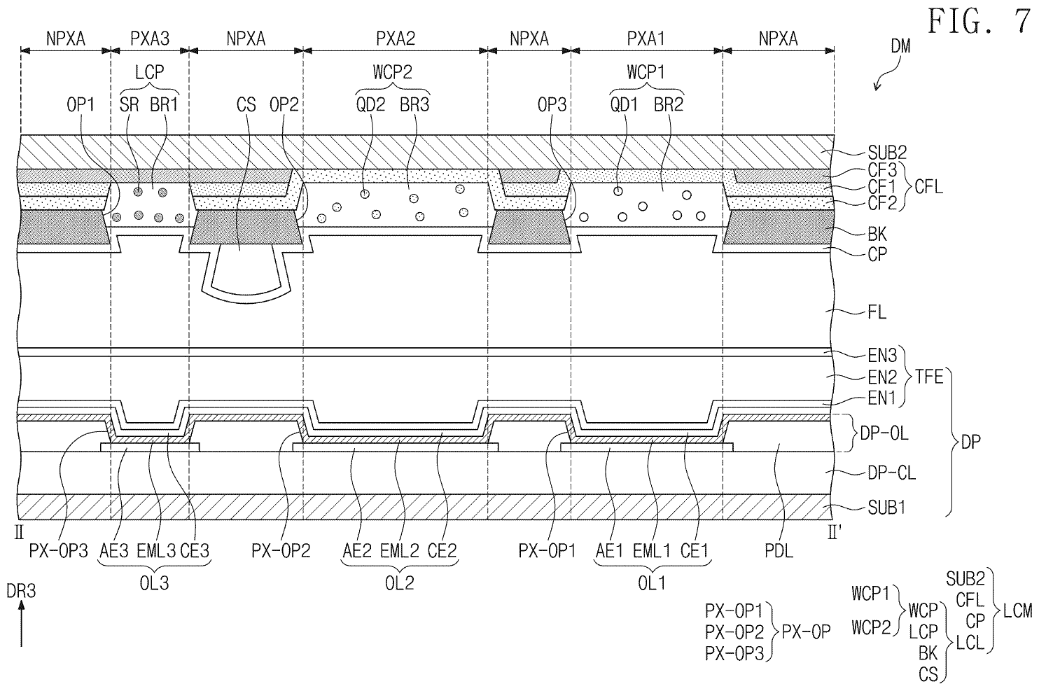

The light control layer LCL is arranged to overlap the display area DA and may include a light transmission layer LCP (see, e.g., FIG. 7) and a light conversion layer WCP (see, e.g., FIG. 7) that converts optical properties of the source light provided by the light-emitting element. The light control layer LCL may selectively convert or transmit a color of the source light. A portion of the light control layer LCL may overlap the peripheral area NDA.

The color filter layer CFL may be arranged to overlap the display area DA and may selectively transmit the light converted or transmitted by the light control layer LCL. The color filter layer CFL may prevent or reduce the likelihood of color purity of the display device DD (see, e.g., FIG. 1) being reduced by absorbing light that passes through and is not converted by the light control layer LCL. The color filter layer CFL may include color filters CF1, CF2, and CF3 (see, e.g., FIG. 7) that display the same color as the corresponding pixel. As a result, the color filter layer CFL may filter external light into the same colors as the pixels, and reflection of the external light may be reduced.

A portion of the color filter layer CFL may be arranged to overlap the peripheral area NDA. The color filter layer CFL may include the color filters CF1, CF2, and CF3 (see, e.g., FIG. 7) sequentially laminated within the peripheral area NDA to absorb light emitted or reflected through the peripheral area NDA.

The capping layer CP may be arranged on a bottom surface of a light control layer LCL facing (e.g., opposite to) the display panel DP. The capping layer CP may be arranged on bottom surfaces of the light control layer LCL and the color filter layer CFL. The capping layer CP may cover the light control layer LCL. The bottom surface of the light control layer LCL may be defined as a surface facing (e.g., opposite to) the display panel DP. The capping layer CP may overlap the display area DA and the peripheral area NDA.

The sealing member SAL may be arranged between the display panel DP and the capping layer CP to bond the capping layer CP coupled to the light control layer LCL to the display panel DP. The sealing member SAL may be arranged to overlap the peripheral area NDA.

For example, each of the components of the display panel DP may be arranged on the first base substrate SUB1, and the light control layer LCL, the color filter layer CFL, and the capping layer CP may be arranged on the second base substrate SUB2 through a separate process. Thereafter, the display panel DP and the light control member LCM may be bonded to each other by the sealing member SAL to provide the display module DM. The sealing member SAL may contain an ultraviolet curable material.

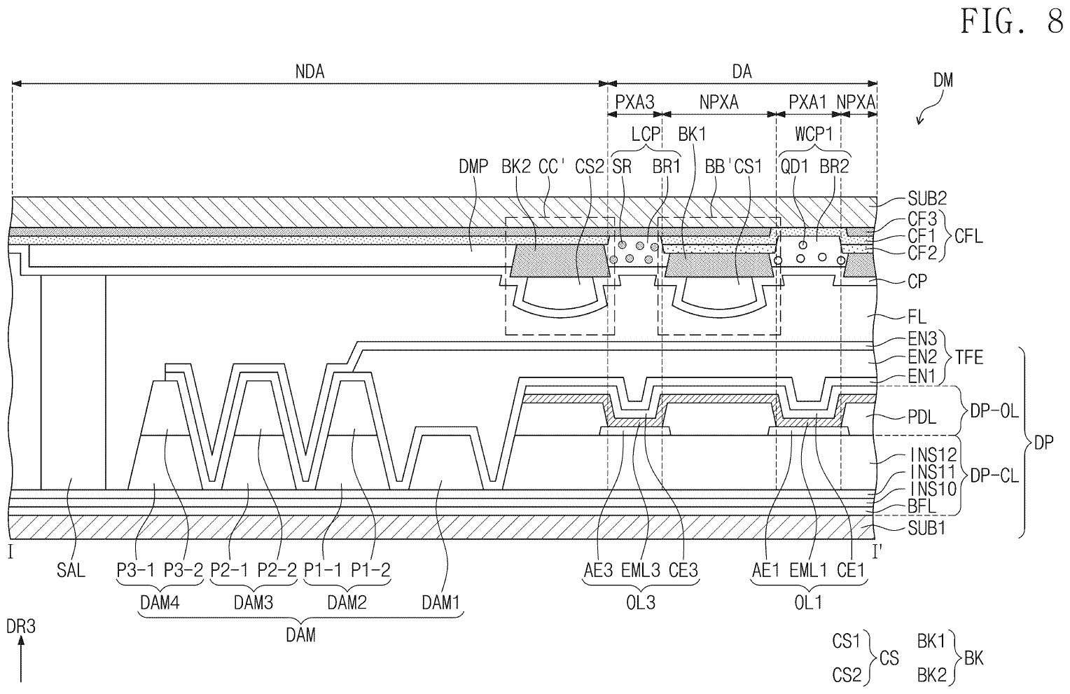

The sealing member SAL has been described as being attached to a bottom surface of the capping layer CP, but the present disclosure is not limited thereto. For example, the sealing member SAL may be attached to an edge of the light control layer LCL. This will be described in more detail with reference to FIG. 8.

The filling member FL may be arranged between the display panel DP and the capping layer CP so as to be filled into (e.g., to fill) an empty space between the display panel DP and the capping layer CP, which overlaps the display area DA. In one or more embodiments, the filling member FL may be arranged between the encapsulation layer TFE and the capping layer CP of the display panel DP. The filler material FL may include a thermosetting material of silicone, epoxy, and/or acrylic series. However, the material of the filler FL may not be limited to the above examples.

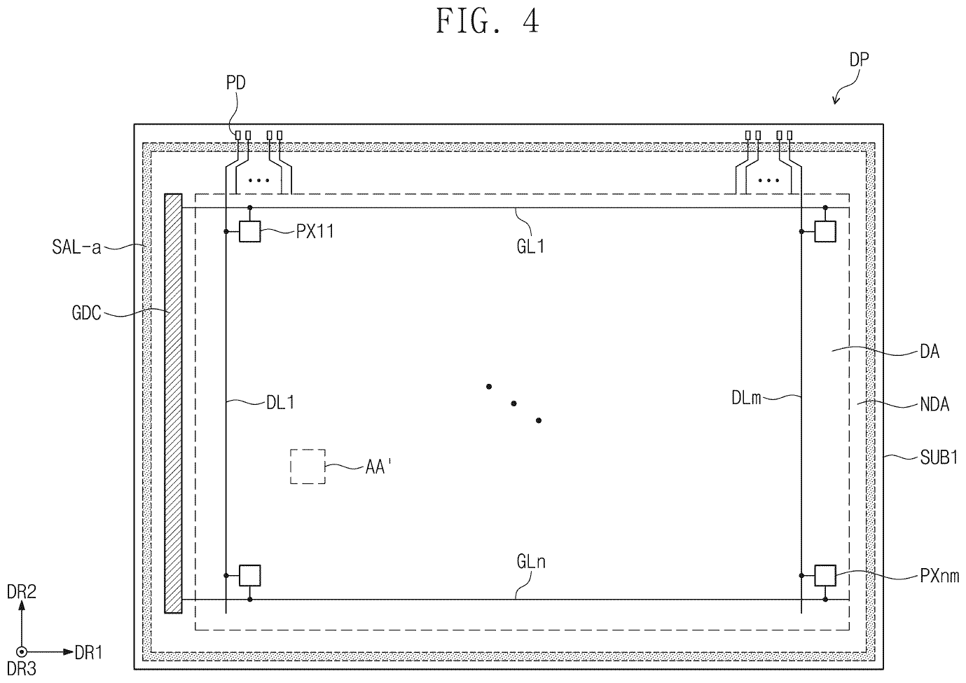

FIG. 4 is a plan view of the display panel according to one or more embodiments of the present disclosure.

Referring to FIG. 4, the first base substrate SUB1 of the display panel DP may include a display area DA and a peripheral area NDA. The display panel DP may include pixels PX11 to PXnm arranged on the display area DA and signal lines GL1 to GLn and DL1 to DLm electrically connected to the pixels PX11 to PXnm. The display panel DP may include a driving circuit GDC and pads PD, which are arranged on (in) the peripheral area NDA.

Each of the pixels PX11 to PXnm may include a light-emitting element that will be described in more detail later, a pixel driving circuit including a plurality of transistors (e.g., a switching transistor, a driving transistor, and/or the like) connected to the light-emitting element, and at least one capacitor. The pixels PX11 to PXnm may be to emit light in response to an electrical signal applied to the pixels PX11 to PXnm. FIG. 4 illustrates the pixels PX11 to PXnm arranged in a matrix form as an example, but the arrangement form of the pixels PX11 to PXnm is not limited thereto.

The signal lines GL1 to GLn and DL1 to DLn may include gate lines GL1 to GLn and data lines DL1 to DLn. Each of the pixels PX11 to PXnm may be connected to a corresponding gate line of the gate lines GL1 to GLn and a corresponding data line of the data lines DL1 to DLm. More types (kinds) of signal lines may be provided on the display panel DP depending on the configuration of the pixel driving circuit of the pixels PX11 to PXnm.

The driving circuit GDC may include a gate driving circuit. The gate driving circuit may generate gate signals and sequentially output the gate signals to the gate lines GL1 to GLn. The gate driving circuit may further output another control signal to the pixel driving circuit of the pixels PX11 to PXnm.

The pads PD may be arranged along one direction on the peripheral area NDA. The pads PD may be portions that are connected to a circuit board. Each of the pads PD may be connected to a corresponding signal line of the plurality of signal lines GL1 to GLn and DL1 to DLn and may be connected to a corresponding pixel through the signal line. The pads PD may have a shape that is integrated with the signal lines GL1 to GLn and DL1 to DLn. However, the present disclosure is not limited thereto, and the pads PD may be arranged on a layer that is different from the layer on which the signal lines GL1 to GLn and DL1 to DLn are arranged, and may be connected to the signal lines GL1 to GLn and DL1 to DLn through contact holes.

FIG. 4 illustrates an example of a sealing member placement area SAL-a corresponding to an area on which the sealing member SAL (see, e.g., FIG. 3) is arranged, on the plane (e.g., in a plan view). The sealing member placement area SAL-a may overlap the peripheral area NDA and may correspond to a portion of the peripheral area NDA. The sealing member placement area SAL-a may be adjacent to an edge of the display panel DP and extend along an extension direction of the edge of the display panel DP. The sealing member placement area SAL-a may be around (e.g., surround) the display area DA on the plane (e.g., in a plan view). In one or more embodiments, the sealing member placement area SAL-a may be defined outside the driving circuit GDC.

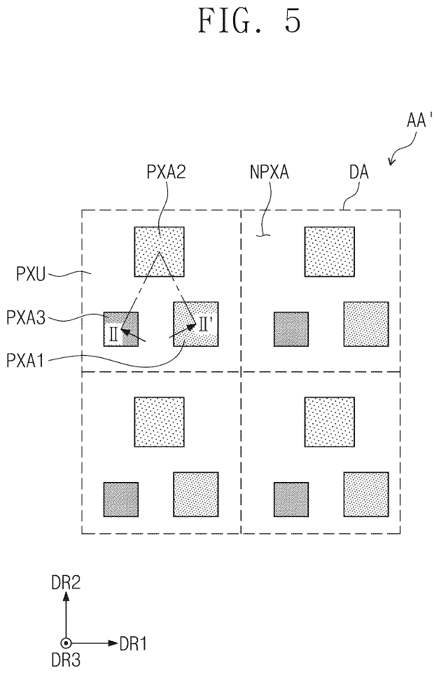

FIG. 5 is an enlarged view of an area AA′ of FIG. 4, according to one or more embodiments of the present disclosure.

Referring to FIG. 5, the display area DA may include a plurality of unit pixels PXU. The unit pixels PXU may be arranged in the first direction DR1 and the second direction DR2. For example, four unit pixels PXU are illustrated in FIG. 5, but the number of unit pixels PXU may not be limited thereto. Hereinafter, one unit pixel PXU of the plurality of unit pixels PXU will be described.

The unit pixel PXU may include emission areas PXA1, PXA2, and PXA3 corresponding to the light-emitting elements and a non-emission area NPXA around (e.g., surrounding) the emission areas PXA1, PXA2, and PXA3. FIG. 5 illustrates the shapes of the emission areas PXA1, PXA2, and PXA3 as an example.

The emission areas PXA1, PXA2, and PXA3 may correspond to areas from which light provided from the light-emitting element is to be emitted. The emission areas PXA1, PXA2, and PXA3 may include a first emission area PXA1, a second emission area PXA2, and a third emission area PXA3. The first to third emission areas PXA1, PXA2, and PXA3 may be distinguished according to colors of light emitted toward the outside of the display device DD (see, e.g., FIG. 1). The non-emission area NPXA may set a boundary between the first to third emission areas PXA1, PXA2, and PXA3 and may prevent or reduce the likelihood of colors being mixed between the first to third emission areas PXA1, PXA2, and PXA3.

One of the first to third emission areas PXA1, PXA2, and PXA3 may provide first color light corresponding to the source light provided by the light-emitting element, another may provide second color light different from the first color light, and another may provide third color light different from the first and second color light. For example, the first color light may be blue light, the second color light may be red light, and the third color light may be green light. However, the present disclosure is not necessarily limited to the above examples.

In one or more embodiments, the first to third emission areas PXA1, PXA2, and PXA3 may have the same shape on the plane (e.g., in a plan view), but different planar areas.

The second emission areas PXA2 arranged along the first direction DR1 may define a first row, and the first emission areas PXA1 and the third emission areas PXA3, which are arranged along the first direction DR1, may define a second row. In the second row, the first emission areas PXA1 and the third emission areas PXA3 may be arranged alternately along the first direction DR1.

The second emission areas PXA2 included in the first row may be provided in a plurality and arranged along the second direction DR2, and similarly, the first emission areas PXA1 and the third emission areas PXA3 included in the second row may be provided in plurality and arranged along the second direction DR2. As illustrated in FIG. 5, the first rows and the second rows may be arranged alternately along the second direction DR2.

Each of the first to third emission areas PXA1, PXA2, and PXA3 may have a rectangular shape, and the planar areas of the first to third emission areas PXA1, PXA2, and PXA3 may be different from each other. As an example, FIG. 5 illustrates the first to third emission areas PXA1, PXA2, and PXA3 having right-angled corners, but the present disclosure is not limited thereto, and the first to third emission areas PXA1, PXA2, and PXA3 may have shapes with substantially rounded corners.

According to one or more embodiments, when viewed on the plane (e.g., in a plan view), the surface area of each of the second emission areas PXA2 may be larger than the surface areas of each of the first and third emission areas PXA1 and PXA3. When viewed on the plane (e.g., in a plan view), the surface area of each of the first emission areas PXA1 may be greater than that of each of the third emission areas PXA1. For example, the surface areas of the second emission areas PXA2 may be the largest, and the surface areas of the third emission areas PXA3 may be the smallest.

The arrangement of the first to third emission areas PXA1, PXA2, and PXA3 illustrated in FIG. 5 is only an example and the present disclosure is not limited thereto, and the arrangement of the first to third emission areas PXA1, PXA2, and PXA3 may vary depending on the design of the display device DD (see, e.g., FIG. 1). The shape, the surface area, the arrangement, and/or the like, of the emission areas may be designed in one or more suitable manners according to light emission efficiency and/or according to the color, and are not limited to one or more embodiments illustrated in FIG. 5.

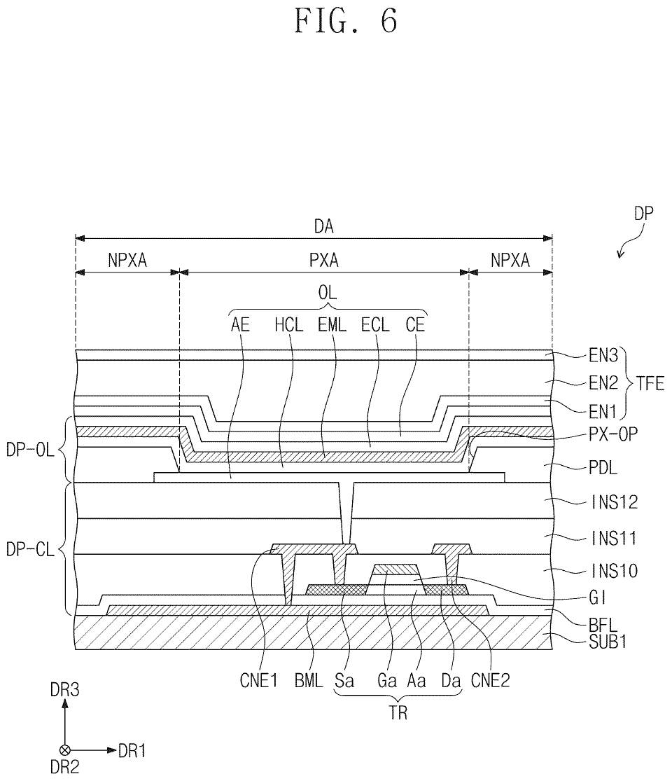

FIG. 6 is a cross-sectional view of the display panel according to one or more embodiments of the present disclosure.

Referring to FIG. 6, the display panel DP may include a first base substrate SUB1, a circuit layer DP-CL, a light-emitting element layer DP-OL, and an encapsulation layer TFE, and description of each component may be applied to the above description.

For example, the emission area PXA illustrated in FIG. 6 may be one of the first to third emission areas PXA1, PXA2, and PXA3 illustrated in FIG. 5, according to one or more embodiments.

The display panel DP may include insulating layers, semiconductor patterns, conductive patterns (layers), and signal lines. In the manufacturing of the display panel DP, the insulating layers, the semiconductor layer, and/or the conductive layers may be formed on the first base substrate SUB1 by coating, deposition, or other methods. Thereafter, the insulating layers, the semiconductor layers, and/or the conductive layers may be selectively patterned using photolithography. Due to this process, the semiconductor patterns, the conductive patterns, the signal lines, and/or the like, included in the display panel DP may be formed.

Each of the pixels may have an equivalent circuit including transistors, at least one capacitor, and a light-emitting element, and an equivalent circuit diagram of the pixel may be modified in one or more suitable ways to various forms. The semiconductor patterns may be arranged in a set or predetermined order across the pixels according to the equivalent circuit diagram. FIG. 6 illustrates an example of one transistor TR and a light-emitting element OL included in a pixel.

Referring to FIG. 6, the first base substrate SUB1 may provide a base surface on which the circuit layer DP-CL is to be formed. The first base substrate SUB1 may have a single-layer or multi-layer structure. For example, the first base substrate SUB1 having the multi-layer structure may include synthetic resin layers and at least one inorganic layer arranged between the synthetic resin layers or may include a glass substrate and a synthetic resin layer arranged on the glass substrate.

The synthetic resin layer included in the first base substrate SUB1 may include at least one of an acrylic resin, a methacrylic resin, a polyisoprene, a vinyl resin, an epoxy resin, a urethane resin, a cellulose resin, a siloxane resin, a polyamide resin, a perylene resin, or a polyimide resin. However, the material of the first base substrate SUB1 is not limited to the above examples.

The circuit layer DP-CL may be arranged on the first base substrate SUB1. The circuit layer DP-CL may include at least one insulating layer, a conductive pattern, and a semiconductor pattern. The laminated structure of the circuit layer DP-CL may be variously modified depending on the process of manufacturing the circuit layer DP-CL or the configuration of the elements included in the pixel, and FIG. 6 illustrates an example of the laminated form of the circuit layer DP-CL. However, this is merely an example, and the present disclosure is not limited thereto, as long as embodiments of the circuit layer DP-CL include driving elements that drive the pixels.

The circuit layer DP-CL may include a light blocking pattern BML, a transistor TR, connection electrodes CNE1 and CNE2, an insulating pattern GI, and a plurality of insulating layers INS10, INS11, and INS12.

The light blocking pattern BML may be arranged on the first base substrate SUB1. The light blocking pattern BML may overlap the transistor TR. The light blocking pattern BML may prevent or reduce the likelihood of conductive patterns included in the circuit layer DP-CL being visually recognized from the outside due to external light, and/or may prevent or reduce the likelihood of the semiconductor layer included in the transistor TR being damaged by the external light.

A buffer layer BFL may be arranged on the first base substrate SUB1 to cover a portion of the light blocking pattern BML. The buffer layer BFL may have a contact hole defined that exposes a portion of the light blocking pattern BML. The buffer layer BFL may improve bonding strength between the first base substrate SUB1 and the semiconductor pattern.

The buffer layer BFL may contain an inorganic material. For example, the buffer layer BFL may include at least one of aluminum oxide, titanium oxide, silicon oxide, silicon nitride, silicon oxynitride, zirconium oxide, or hafnium oxide. However, the material of the buffer layer BFL is not limited to the above examples.

The semiconductor pattern of the transistor TR may be arranged on the buffer layer BFL. The semiconductor pattern may include polysilicon. However, the present disclosure is not limited thereto, and the semiconductor pattern may include amorphous silicon, crystalline oxide, or non-crystalline oxide.

A source region Sa, a drain region DA, and a channel region Aa of the transistor TR may be defined in a semiconductor pattern. The semiconductor pattern may be divided into a plurality of regions according to conductivity. For example, the semiconductor pattern may have different electrical properties depending on whether the semiconductor pattern is doped or whether a metal oxide is reduced. A region having high conductivity in the semiconductor pattern may serve as an electrode or signal line and may correspond to a source region Sa and/or a drain region DA of the transistor TR. A non-doped or non-reduced region having relatively little conductivity may correspond to the channel region (or active region) of the transistor TR.

After providing the insulating layer on the semiconductor pattern of the transistor TR, an insulating pattern GI may be provided by patterning. A gate electrode Ga may be arranged on the insulating pattern GI. The gate electrode Ga may be used as a mask in the process of forming the insulating pattern GI. The gate electrode Ga may overlap the channel region Aa and be spaced and/or apart (e.g., spaced apart or separated) from the semiconductor pattern of the transistor TR in a cross-sectional view with the insulating pattern GI therebetween.

The plurality of insulating layers INS10, INS11, and INS12 may be arranged on the buffer layer BFL. Each of the plurality of insulating layers INS10, INS11, and INS12 may include at least one inorganic film or organic film. For example, the inorganic film of the insulating layers INS10, INS11, and INS12 may include at least one of aluminum oxide, titanium oxide, silicon oxide, silicon nitride, silicon oxynitride, zirconium oxide, or hafnium oxide, but the present disclosure is not limited to the above materials. The organic film of the insulating layers INS10, INS11, and INS12 may include a phenol-based polymer, an acrylic-based polymer, an imide-based polymer, an aryl ether-based polymer, an amide-based polymer, a fluorinated polymer, a p-xylene-based polymer, a vinyl alcohol-based polymer, and/or a polymer containing a combination thereof, but the present disclosure is not limited to the above materials.

The first insulating layer INS10 may be arranged on the buffer layer BFL to cover the gate electrode Ga. The first insulating layer INS10 may define at least one contact hole that exposes a portion of the semiconductor pattern of the transistor TR.

The connection electrodes CNE1 and CNE2 may include a first connection electrode CNE1 and a second connection electrode CNE2 arranged on the first insulating layer INS10. The first connection electrode CNE1 may be connected to the source region Sa of the transistor TR through a contact hole passing through the first insulating layer INS10. In one or more embodiments, the first connection electrode CNE1 may be connected to the light blocking pattern BML through a contact hole passing through the first insulating layer INS10 and the buffer layer BFL. The second connection electrode CNE2 may be connected to the drain region DA of the transistor TR through a contact hole passing through the first insulating layer INS10. The second connection electrode CNE2 may extend on the plane (e.g., may extend in the first or second direction DR1, DR2) and be connected to another transistor or line.

The second insulating layer INS11 and the third insulating layer INS12 may be arranged on the first insulating layer INS10 to cover the connection electrodes CNE1 and CNE2. The second insulating layer INS11 and the third insulating layer INS12 may define a through-hole that exposes a portion of the first connection electrode CNE1, and the first connection electrode CNE1 may be connected to the first electrode AE of the light-emitting element OL arranged on the third insulating layer INS12. In one or more embodiments, the third insulating layer INS12 may include an organic film and may provide a flat top surface. However, the present disclosure is not necessarily limited thereto.

The light-emitting element layer DP-OL may be arranged on the circuit layer DP-CL. The light-emitting element layer DP-OL may include a plurality of light-emitting elements OL and a pixel-defining layer PDL, and FIG. 6 illustrates a cross-section corresponding to one light-emitting element OL of the plurality of light-emitting elements OL. The light-emitting element OL may be defined by the first electrode AE, a portion of the hole control layer HCL arranged in a light-emitting opening PX-OP to be described in more detail later, a portion of the emission layer EML, a portion of the electron control layer ECL, and a portion of the second electrode CE.

The display area DA may include an emission area PXA corresponding to the emitting element OL and the non-emission area NPXA around (e.g., surrounding) the emission area PXA. The light-emitting element OL may include the first electrode AE, the hole control layer HCL, the emission layer EML, the electron control layer ECL, and the second electrode CE.

The first electrode AE may be arranged on a top surface of the third insulating layer INS12. The first electrode AE may be connected to the first connection electrode CNE1 through a through-hole passing through the second insulating layer INS11 and the third insulating layer INS12.

The pixel-defining layer PDL may be arranged on the third insulating layer INS2. The pixel-defining layer PDL may define a light-emitting opening PX-OP that exposes a portion of the first electrode AE. The pixel-defining layer PDL may cover a portion of the top surface of the first electrode AE. In one or more embodiments, a portion of the first electrode AE exposed by the light-emitting opening PX-OP may correspond to the emission area PXA. The area on which the pixel-defining layer PDL is arranged may correspond to the non-emission area NPXA around (e.g., surrounding) the emission area PXA.

The pixel-defining layer PDL may include a polymer resin. For example, the pixel-defining layer PDL may include a polyacrylate-based resin or a polyimide-based resin. The pixel-defining layer PDL may be made by further including an inorganic material in addition to the polymer resin. In one or more embodiments, the pixel-defining layer PDL may include an inorganic material. For example, the pixel-defining layer PDL may include silicon nitride (SiₓN_{y}, where, e.g., 0<x≤3 and 0<y≤4), silicon oxide (SiOₓ, where, e.g., 0<x≤2), silicon oxynitride (SiOₓN_{y}, where, e.g., 0<x≤2 and 0<y≤2), and/or the like.

In one or more embodiments, the pixel-defining layer PDL may include a light absorbing material. The pixel-defining layer PDL may include a black coloring agent. The back coloring agent may include a black dye and/or a black pigment. The black coloring agent may include carbon black, a metal such as chromium, or oxides thereof. However, the material of the pixel-defining layer PDL is not limited to the above examples.

The hole control layer HCL may be arranged on the first electrode AE and the pixel-defining layer PDL. The hole control layer HCL may be commonly arranged across the plurality of pixels. A portion of the hole control layer HCL may be arranged in the light-emitting opening PX-OP. The hole control layer HCL may overlap the emission area PXA and the non-emission area NPXA. The hole control layer HCL may include at least one of a hole transport layer or a hole injection layer.

The emission layer EML may be arranged on the hole control layer HCL. The emission layer EML may be commonly arranged across the plurality of pixels. A portion of the emission layer EML may be arranged in the emitting opening PX-OP and overlap the emission area PXA. The emission layer EML may overlap the emission area PXA and the non-emission area NPXA.

The emission layer EML may include an organic light-emitting material, an inorganic light-emitting material, a quantum dot, or a quantum rod. In one or more embodiments, the emission layer EML may be provided in the form of a separate emission pattern for each pixel. However, the present disclosure is not limited thereto, and the emission layer EML may be provided as a common layer that is commonly provided to the pixels. The emission layer EML may generate first light, which is the source light. For example, the first light may be blue light, but the present disclosure is not necessarily limited thereto.

In one or more embodiments, the light-emitting element OL may be a light-emitting element having a tandem structure including a plurality of emission layers. The plurality of emission layers may be laminated along a thickness direction on the first electrode AE. Some of the plurality of emission layers may generate light having substantially the same color, while others may generate light having different colors. For example, the light-emitting element OL according to one or more embodiments may include four emission layers, three of the four emission layers may generate blue light, and one emission layer may generate green light. However, this is only an example, and the structure of the emission layer EML is not necessarily limited thereto. The light-emitting element having the tandem structure may further include functional layers such as a hole control layer, an electron control layer, and a charge generation layer arranged between the plurality of emission layers.

The electronic control layer ECL may be arranged on the emission layer EML. The electronic control layer ECL may be commonly arranged across the plurality of pixels. A portion of the electronic control layer ECL may be arranged in the light-emitting opening PX-OP. The electronic control layer ECL may overlap the emission area PXA and the non-emission area NPXA. The electron control layer ECL may include at least one of the electron transport layer or an electron injection layer.

The second electrode CE may be arranged on the electronic control layer ECL. The second electrode CE may be commonly arranged across the plurality of pixels. The second electrode CE may overlap the emission area PXA and the non-emission area NPXA. A common voltage may be provided to the second electrode CE, and the second electrode CE may be referred to as a common electrode.

A first voltage may be applied to the first electrode AE through the transistor TR, and the common voltage may be applied to the second electrode CE. When holes and electrons injected into the emission layer EML are coupled to form excitons, the light-emitting element OL may be to emit light when the excitons are transited to the ground state.

The encapsulation layer TFE may be arranged on the light-emitting element layer DP-OL to seal the light-emitting element layer DP-OL. The encapsulation layer TFE may include first to third encapsulation films EN1, EN2, and EN3. The first encapsulation film EN1 may be arranged on the second electrode CE, and the second encapsulation film EN2 and the third encapsulation film EN3 may be sequentially arranged on the first encapsulation film EN1.

In one or more embodiments, each of the first and third encapsulation films EN1 and EN3 may include an inorganic film. The inorganic film may protect the light-emitting element layer DP-OL against moisture and/or oxygen. For example, the inorganic film may include at least one of aluminum oxide, titanium oxide, silicon oxide, silicon nitride, silicon oxynitride, zirconium oxide, or hafnium oxide, but the present disclosure is not limited to the above examples.

In one or more embodiments, the second encapsulation film EN2 may include an organic film, and the organic film may protect the light-emitting element layer DP-OL against foreign substances such as dust particles. For example, the organic film may include an acrylic resin, but the present disclosure is not limited to the above examples.

FIG. 7 is a cross-sectional view of the display module taken along the line II-II′ of FIG. 5, according to one or more embodiments of the present disclosure. Other pixel units PXU throughout the display panel DP may have the same or similar configuration to that discussed above and discussed in more detail below with respect to FIG. 7.

For conciseness and clarity, the circuit layer DP-CL is simply illustrated as a single layer. In addition, in FIG. 7, the hole control layer HCL (see, e.g., FIG. 6) and the electron control layer ECL (see, e.g., FIG. 6) of the light-emitting elements OL are not provided for conciseness and clarity purposes.

In the components illustrated in FIG. 7, descriptions of the same components as the above-described components may not be provided or may only be briefly described with reference to the accompanying drawings.

Referring to FIG. 7, the light-emitting opening PX-OP may be defined by the pixel-defining layer PDL. The light-emitting opening PX-OP may include a first light-emitting opening PX-OP1, a second light-emitting opening PX-OP2, and a third light-emitting opening PX-OP3.

The first light-emitting opening PX-OP1 may overlap the first pixel area PXA1. The second light-emitting opening PX-OP2 may overlap the second pixel area PXA2. A third light-emitting opening PX-OP3 may overlap the third pixel area PXA3.

A length of the third light-emitting opening PX-OP3 in the first direction DR1 may be less than a length of each of the first and second light-emitting openings PX-OP1 and PX-OP2 in the first direction DR1. A length of the first light-emitting opening PX-OP1 in the first direction DR1 may be less than a length of the second light-emitting opening PX-OP2 in the first direction DR1.

The light-emitting elements OL1, OL2, and OL3 may include a first light-emitting element OL1, a second light-emitting element OL2, and a third light-emitting element OL3. The first light-emitting element OL1 may be arranged in the first light-emitting opening PX-OP1 and may overlap the first emission area PXA1. The second light-emitting element OL2 may be arranged in the second light-emitting opening PX-OP2 and may overlap the second emission area PXA2. The third light-emitting element OL3 may be arranged in the third light-emitting opening PX-OP3 and may overlap the third emission area PXA3.

The first to third light-emitting elements OL1, OL2, and OL3 may include first electrodes AE1, AE2, and AE3, emission layers EML1, EML2, and EML3, and second electrodes CE1, CE2, and CE3, respectively. In other words, the first light-emitting element OL1 may include the first electrode AE1, the emission layer EML1, and the second electrode CE1; the second light-emitting element OL2 may include the first electrode AE2, the emission layer EML2, and the second electrode CE2; and the third light-emitting element OL3 may include the first electrode AE3, the emission layer EML3, and the second electrode CE3.

The first electrodes AE1, AE2, and AE3 of the first to third light-emitting elements OL1, OL2, and OL3 may be arranged to be spaced and/or apart (e.g., spaced apart or separated) from each other on the circuit layer DP-CL. In one or more embodiments, the first electrodes AE1, AE2, and AE3 of the first to third light-emitting elements OL1, OL2, and OL3 may be connected to transistors of the corresponding circuit layers DP-CL, respectively. The first electrodes AE1, AE2, and AE3 may be connected to other transistors by the directly connected transistors and the first electrodes AE1, AE2, and AE3 may be connected to at least one capacitor.

The filler member FL may be arranged between the display panel DP and the light control member LCM. A gap between the display panel DP and the light control member LCM may be filled by the filler member FL. However, the present disclosure is not limited thereto. For example, the filler member FL may not be provided, and the light control member LCM may be arranged directly on the display panel DP.

The light control member LCM may be arranged on the filler member FL. The light control member LCM may be arranged on the display panel DP. The filler layer FL may be arranged between the display panel DP and the capping layer CP to be described in more detail later.

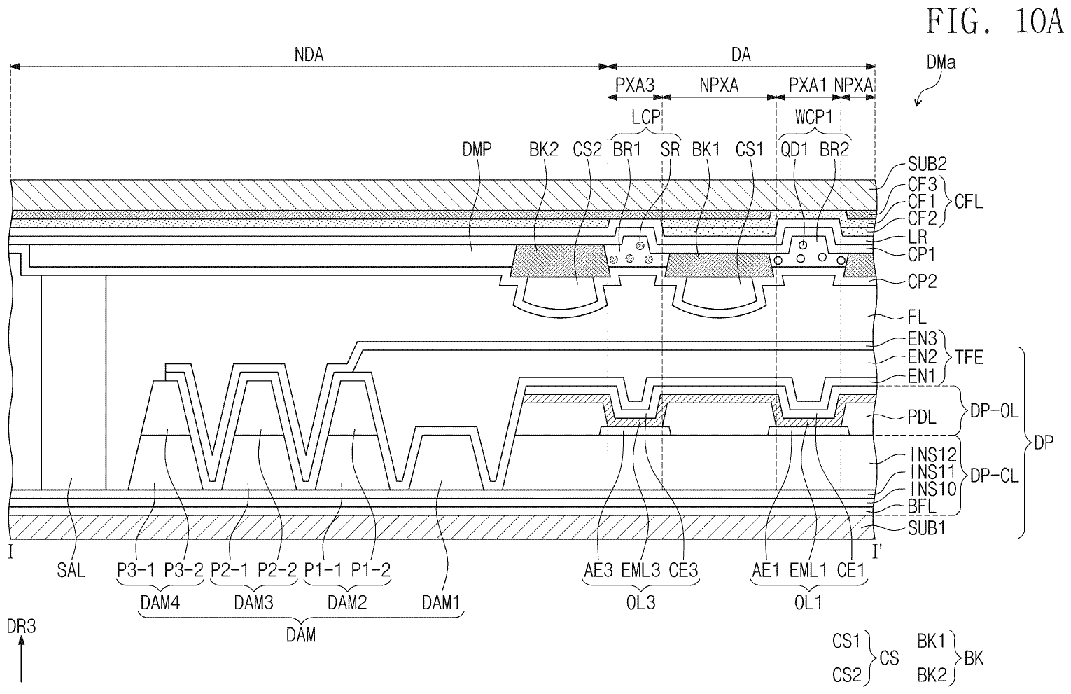

The light control member LCM may include an upper substrate SUB2, a color filter layer CFL, a light control layer LCL, and a capping layer CP. The color filter layer CFL, the light control layer LCL, and the capping layer CP may be sequentially arranged on a rear surface of the upper substrate SUB2 in the third direction DR3. The rear surface of the upper substrate SUB2 may be defined as a surface facing (e.g., opposite to) the top surface of the lower substrate SUB1. The light control member LCM according to one or more embodiments may further include a low refractive layer LR as illustrated in FIG. 10A.

The light control layer LCL may include a light conversion layer WCP, a light transmission layer LCP, a bank layer BK, and a spacer CS. Each of the light conversion layer WCP and the light transmission layer LCP may be referred to as a light control part. The bank layer BK may be arranged on a bottom surface of the color filter layer CFL. The bottom surface of the color filter layer CFL may be defined as a surface facing (e.g., opposite to) the display panel DP. The bank layer BK may overlap the non-emission area NPXA. When viewed in the second direction DR2, the bank layer BK may be provided as a plurality of layers, but substantially, the bank layer may have an integrated shape.

The bank layer BK may include a black pigment and/or a black dye and water-repellent substances. The bank layer BK may have a black color as the bank layer BK contains a black pigment and/or dye. Thus, the bank layer BK may block or reduce light so that light emitted from the light-emitting elements OL1, OL2, and OL3 are not mixed with each other. In one or more embodiments, when viewed on the plane (e.g., in a plan view), the first to third emission areas PXA1 to PXA3 may be surrounded by the bank layer BK.

A plurality of openings OP1, OP2, and OP3 may be defined by the bank layer BK. The openings OP1, OP2, and OP3 may be spaced and/or apart (e.g., spaced apart or separated) from each other on the plane (e.g., in a plan view). The first opening OP1 may overlap the third light-emitting element OL3. The second opening OP2 may overlap the second light-emitting element OL2. The third opening OP3 may overlap the first light-emitting element OL1.

The light transmission layer LCP may be arranged between the display panel DP and the color filter layer CFL. For example, the light transmission layer LCP may be arranged between the capping layer CP and the color filter layer CFL. The light transmission layer LCP may be arranged on a bottom surface of the color filter layer CFL. The bottom surface of the color filter layer CFL may be defined as a surface facing (e.g., opposite to) the display panel DP. The light transmission layer LCP may be arranged in the first opening OP1 defined by the bank layer BK.

The light transmission layer LCP may overlap the third emission area PXA3 and the non-emission areas NPXA adjacent to the third emission area PXA3. The light transmission layer LCP may overlap the third light-emitting element OL3.

The light transmission layer LCP may include a first base resin BR1 and scatterers (e.g., scattering particles) SR dispersed in the first base resin BR1. The scatterers SR may scatter light incident from the third light-emitting element OL3 to the light transmission layer LCP in various directions. The scatterers SR may be particles having relatively high density or specific gravity. For example, the scatterers SR may include titanium oxide (TiOₓ, where, e.g., 0, x≤2) or silica-based nanoparticles. The scatterers SR may improve light emission efficiency of light provided from the light-emitting element and passing through the light transmission layer LCP.

The light transmission layer LCP may be to transmit the first light provided from the third light-emitting element OL3. For example, the third light-emitting element OL3 may provide the blue light to the light transmission layer LCP, and the blue light may pass through the light transmission layer LCP and be emitted toward the front side of the display module DM. The light transmission layer LCP may be provided through a photolithography process.

The light conversion layers WCP may be arranged in the second and third openings OP2 and OP3. The light conversion layers WCP may be arranged between the display panel DP and the color filter layer CFL. For example, the light conversion layers WCP may be arranged between the capping layer CP and the color filter layer CFL. The light conversion layers WCP and the light transmission layer LCP may be arranged on the same layer.

The light conversion layers WCP may overlap the first emission area PXA1 and the second emission area PXA2. The light conversion layers WCP may overlap the first light-emitting element OL1 and the second light-emitting element OL2.

The light conversion layers WCP may include a first light conversion layer WCP1 and a second light conversion layer WCP2. The first light conversion layer WCP1 may be arranged in the third opening OP3. The second light conversion layer WCP2 may be arranged in the second opening OP2. On the plane (e.g., in a plan view), the first and second light conversion layers WCP1 and WCP2 and the light transmission layer LCP may be arranged to be spaced and/or apart (e.g., spaced apart or separated) from each other.

The first light conversion layer WCP1 may overlap the first emission area PXA1. The first light conversion layer WCP1 may overlap the first light-emitting element OL1. The second light conversion layer WCP2 may overlap the second emission area PXA2. The second light conversion layer WCP2 may overlap the second light-emitting element OL2.

A width of the second light conversion layer WCP2 may be greater than a width of each of the first light conversion layer WCP1 and the light transmission layer LCP. The width of the first light conversion layer WCP1 may be greater than the width of the light transmission layer LCP. For example, the width of the second light conversion layer WCP2 may be the largest, and the width of the light transmission layer LCP may be the smallest.

The first light conversion layer WCP1 may include a second base resin BR2 and first quantum dots QD1 dispersed in the second base resin BR2. The second light conversion layer WCP2 may include a third base resin BR3 and second quantum dots QD2 dispersed in the third base resin BR3.

Cores (discussed in more detail below) of the quantum dots QD1 and QD2 included in each of the first light conversion layer WCP1 and the second light conversion layer WCP2 may be at least one selected from among the Group II-VI compounds, the Group III-VI compounds, the Group I-III-VI compounds, the Group III-V compounds, the Group IV-VI compounds, the Group IV elements, the Group IV compounds, and/or a (e.g., any suitable) combination thereof.

The Group II-VI compounds may be selected from the group consisting of binary element compounds selected from the group consisting of CdSe, CdTe, ZnS, ZnSe, ZnTe, ZnO, HgS, HgSe, HgTe, MgSe, MgS, and/or a (e.g., any suitable) mixture thereof, ternary element compounds selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or a (e.g., any suitable) mixture thereof, and quaternary element compounds selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and/or a (e.g., any suitable) mixture thereof.

The Group III-VI compounds may include binary element compounds such as In2S3, In2Se3, and/or the like, ternary element compounds such as InGaS3, InGaSe3, and/or the like, or any combination thereof.

The Group I-III-VI compounds may be selected from among ternary element compounds such as AgInS, AgInS₂, CuInS, CuInS₂, AgGaS₂, CuGaS₂, CuGaO₂, AgGaO₂, AgAlO₂, and/or a (e.g., any suitable) mixture thereof or quaternary element compounds such as AgInGaS₂, CuInGaS₂, and/or the like.

The Group III-V compounds may be selected from the group consisting of binary element compounds selected from the group consisting of GaN, GaP, GaAs, GaSb, AlN, AlP, AlAs, AlSb, InN, InP, InAs, InSb, and/or a (e.g., any suitable) mixture thereof, ternary element compounds selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and/or a (e.g., any suitable) mixture thereof, and quaternary element compounds selected form the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or a (e.g., any suitable) mixture thereof. The Group III-V compounds may further include the Group II metals. For example, InZnP may be selected from the Group III-II-V compounds.

The Group IV-VI compounds may be selected from among binary element compounds selected from the group consisting of SnS, SnSe, SnTe, PbS, PbSe, PbTe, and/or a (e.g., any suitable) combination thereof, ternary element compounds selected from the group consisting of SnSeS, SnSeTe, SnSTe, PbSeS, PbSeTe, PbSTe, SnPbS, SnPbSe, SnPbTe, and/or a (e.g., any suitable) combination thereof, and quaternary element compounds selected from the group consisting of SnPbSSe, SnPbSeTe, SnPbSTe, and/or a (e.g., any suitable) combination thereof. The Group IV elements may be selected from the group consisting of Si, Ge, and/or a (e.g., any suitable) mixture thereof. The Group IV compounds may be binary element compounds selected from the group consisting of SiC, SiGe, and/or a (e.g., any suitable) mixture thereof.

Each element included in multi-element compounds such as the binary element compounds, the ternary element compounds, and/or the quaternary element compounds may be present in the particles at a substantially uniform concentration or substantially non-uniform concentration. For example, the chemical formula may refer to the type (kind) of elements included in the compounds, and one or more suitable element ratios of the compounds may be used. For example, AgInGaS₂ may refer to AgInₓGa1-xS₂ (where x is a real number between 0 and 1).

The quantum dot may have a single structure or a core-shell dual structure in which elements contained in the quantum dots have a substantially uniform concentration. For example, the material contained in the core and the material contained in the shell may be different from each other.

In one or more embodiments, each of the quantum dots QD1 and QD2 may have a core-shell structure including the above-described nanocrystals. The shell of the quantum dot may serve as a protection layer that prevents the core from being chemically changed in order to maintain the semiconductor characteristics and/or may serve as a filling layer for imparting electrophoretic characteristics to the quantum dot. The shell may have a single-layered or multi-layered shape. An interface between the core and the shell may have a concentration gradient in which an element existing in the shell has a concentration that gradually decreases toward a center. Examples of quantum dot shells include metal oxides, non-metal oxides, semiconductor compounds, and/or a (e.g., any suitable) combination thereof.

For example, the metal oxide or nonmetal oxide may include binary element compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and/or the like or ternary element compounds such as MgAl₂O₄, CoFe₂O₄, NiFe₂O₄, CoMn₂O₄, and/or the like, but the present disclosure is not limited to the above examples.

In one or more embodiments, the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but the present disclosure is not limited thereto.

Each element included in multi-element compounds, such as the binary element compounds and the ternary element compounds, may be present in the particles at a substantially uniform concentration or substantially non-uniform concentration. For example, the chemical formula may refer to the type (kind) of elements included in the compounds, and one or more suitable element ratios of the compounds may be used.

Each of the quantum dots QD1 and QD2 may have a full width of half maximum (FWHM) of an emission wavelength spectrum of about 45 nm or less, about 40 nm or less, or about 30 nm or less. In these ranges, color purity and color reproducibility may be improved. Also, light emitted through the quantum dots QD1 and QD2 may be emitted in all directions to improve an optical viewing angle.

Each of the quantum dots QD1 and QD2 has a shape that is generally used and/or generally available in the art and the shape is not specifically limited. In one or more embodiments, the quantum dot may have a spherical shape, a pyramidal shape, a multi-arm shape, a cubic nanoparticle shape, a nanotube shape, a nanowire shape, a nanofiber shape (e.g., in a form of nanofibers), a nanoplate particle shape, and/or the like.

A color of light emitted by the quantum dots QD1 and QD2 may be controlled or selected by controlling a particle size or an element ratio within the compound, and thus, the quantum dots QD1 and QD2 may have one or more suitable emission colors such as blue, red, and/or green colors. Thus, the first quantum dots QD1 may convert the first light provided by the first light-emitting element OL1 into the second light having a wavelength range different from that of the first light. For example, the first quantum dots QD1 may convert the first light provided by the first light-emitting element OL1 into the red light. Thus, the display module DM may be to emit the red light through the first emission area PXA1.

The second quantum dots QD2 may convert the first light provided by the second light-emitting element OL2 into third light having a wavelength range different from that of the first light. Here, the wavelength range of the second light and the wavelength range of the third light may be different from each other. For example, the second quantum dots QD2 may convert the first light provided by the second light-emitting element OL2 into the green light. Thus, the display module DM may be to emit the green light through the second emission area PXA2.

The spacer CS may be arranged on a rear surface of the bank layer BK adjacent to the light transmission layer LCP. The rear surface of the bank layer BK may be defined as a surface facing (e.g., opposite to) the display panel DP. For example, the spacer CS may be arranged on the rear surface of the bank layer BK adjacent to the light transmission layer LCP, but the position of the spacer CS may vary. For example, the spacer CS may be arranged on the rear surface of the bank layer BK adjacent to one or more of the light conversion layers WCP.

The spacer CS may extend toward the display panel DP. The spacer CS may maintain a gap between the display panel DP and the light control member LCM. For example, the spacer CS may serve to maintain a cell gap (or space) between the display panel DP and the light control member LCM.

A bottom surface of the spacer CS may have a set or predetermined curvature. For example, the bottom surface of the spacer CS may have a partial elliptical shape. The bottom surface of the spacer CS may be defined as a surface facing (e.g., opposite to) the display panel DP.

The spacer CS may include an optically transparent insulating material. The spacer CS may be provided after the light transmission layer LCP and the light conversion layers WCP are provided. However, the present disclosure is not limited thereto. in one or more embodiments, the spacer CS may include a first base resin BR1 and scatterers SR. For example, the spacer CS may contain substantially the same material as the light transmission layer LCP. The spacer CS may be formed concurrently (e.g., simultaneously) with the light transmission layer LCP. The spacer CS may be formed concurrently (e.g., simultaneously) with the light transmission layer LCP through a photolithography process.

The capping layer CP may be arranged on a bottom surface of the light control layer LCL facing (e.g., opposite to) the display panel DP. The capping layer CP may cover the bank layer BK, the spacer CS, the light transmission layer LCP, and the light conversion layers WCP. The capping layer CP may prevent or reduce the likelihood of (e.g., protect from) the moisture or foreign substances being introduced into the light control layer LCL. The capping layer CP may cover a lower portion of the light control layer LCL to protect the light control layer LCL and prevent or reduce deterioration due to the moisture.

The color filter layer CFL may include a first color filter CF1, a second color filter CF2, and a third color filter CF3. The first to third color filters CF1, CF2, and CF3 may be arranged to correspond to the first to third emission areas PXA1, PXA2, and PXA3 on the plane (e.g., in a plan view), respectively. For example, the first color filter CF1 may overlap the first emission area PXA1, the second color filter CF2 may overlap the second emission area PXA2, and the third color filter CF3 may overlap the third emission area PXA3.

Each of the first to third color filters CF1, CF2, and CF3 may include a base resin and a pigment and/or dye dispersed in the base resin. Each of the first to third color filters CF1, CF2, and CF3 may be to transmit light having a specific wavelength range and absorb the light (e.g., most of light) having a wavelength range outside the specific wavelength range.

For example, the first color filter CF1 may include a red color filter. The second color filter CF2 may include a green color filter. The third color filter CF3 may include a blue color filter. The red color filter may be to transmit red light and absorb most of the green and blue light. The green color filter may be to transmit green light and absorb most of the red and blue light. The blue color filter may be to transmit blue light and absorb most of the red and green light.

The first color filter CF1 may be arranged on the first light conversion layer WCP1. The first color filter CF1 may be to transmit the second light provided from the first light conversion layer WCP1. For example, the first light conversion layer WCP1 may convert the first light provided from the first light-emitting element OL1 into the red light, and the first color filter CF1 may be to transmit the red light provided from the first light conversion layer WCP1. The first color filter CF1 may be to absorb the green light and the blue light incident onto the first color filter CF1. The first color filter CF1 may prevent or reduce the likelihood of color purity being reduced within the first emission area PXA1 by absorbing light of the light incident onto the first color filter CF1 that is not changed by the first light conversion layer WCP1.

The second color filter CF2 may be arranged on the second light conversion layer WCP2 to transmit the third light provided from the second light conversion layer WCP2. For example, the second light conversion layer WCP2 may convert the first light provided from the second light-emitting element OL2 into the green light, and the second color filter CF2 may be to transmit the green light provided from the second light conversion layer WCP2. The second color filter CF2 may be to absorb the red light and the blue light incident onto the second color filter CF2. The second color filter CF2 may prevent or reduce the likelihood of color purity being reduced within the second emission area PXA2 by absorbing light of the light incident onto the second color filter CF2 that is not changed by the second light conversion layer WCP2.

The third color filter CF3 may be arranged on the light transmission layer LCP. The third color filter CF3 may overlap the light transmission layer LCP. The third color filter CF3 may be to transmit the first light provided from the third light-emitting element OL3 and passing through the light transmission layer LCP. For example, the third color filter CF3 may be to transmit the blue light and absorb the green light and red light to prevent or reduce the likelihood of the color purity being reduced within the third emission area PXA3.

External light such as natural light may be incident onto the display module DM from outside the display module DM. The external light may include red light, green light, and blue light. If the display module DM does not include the color filter layer CFL, the external light incident onto the display module DM may be reflected by the conductive patterns (e.g., signal lines, electrodes, and/or the like) inside the display module DM and provided to the user, and thus, the user may visually recognize (see) the reflected light.

The first to third color filters CF1, CF2, and CF3 may prevent or reduce reflection of the external light. For example, the first color filter CF1 may be a red color filter and may be to absorb light corresponding to the green light and the blue light in the external light, thereby filtering the external light into the red light. The second color filter CF2 may be a green color filter and may filter the external light into the green light by absorbing light corresponding to the red light and the blue light in the external light. The third color filter CF3 may be a blue color filter and may be to absorb the red and green light in the external light to filter the external light into the blue light. The first to third color filters CF1, CF2, and CF3 arranged to overlap each other in each of the emission areas PXA1, PXA2, and PXA3 may be referred to as filter parts.

At least two color filters of the first to third color filters CF1, CF2, and CF3 may overlap each other within the non-emission area NPXA. For example, the first to third color filters CF1, CF2, and CF3 may be arranged to overlap each other along the third direction DR3 within the non-emission area NPXA. For example, the first color filter CF1 may be arranged under the third color filter CF3, and the second color filter CF2 may be arranged under the first color filter CF1.

The first to third color filters CF1, CF2, and CF3 arranged to overlap each other may extend onto the bank layer BK and overlap each other. The first to third color filters CF1, CF2, and CF3 arranged to overlap each other may block or reduce light passing through the non-emission region NPXA to prevent or reduce the likelihood of the colors being mixed between the first to third emission regions PXA1, PXA2, and PXA3. The first to third color filters CF1, CF2, and CF3 arranged to overlap each other in the non-emission area NPXA may be referred to as blocking parts.

The upper substrate SUB2 may be arranged on the color filter layer CFL. The upper substrate SUB2 may include a glass substrate, a polymer substrate, and/or an organic/inorganic composite material substrate. The upper substrate SUB2 may include front and rear surfaces that are parallel to the first direction DR1 and the second direction DR2, respectively. The rear surface of the upper substrate SUB2 may face the top surface of the lower substrate SUB1. The upper substrate SUB2 may provide a base surface on which the components of the light control member LCM are laminated.

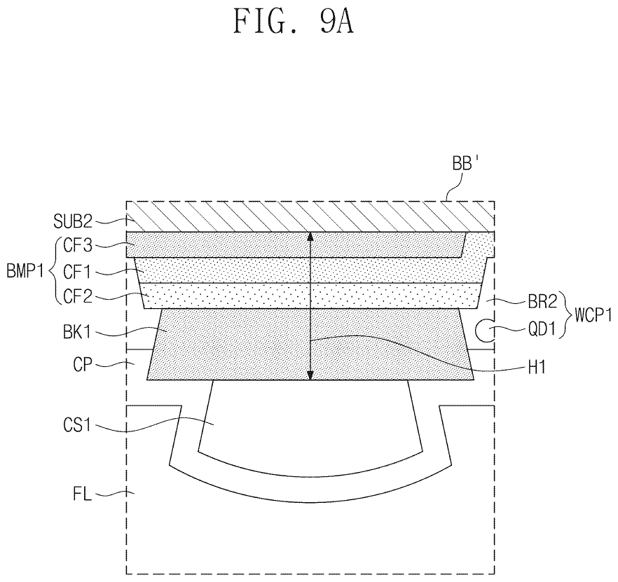

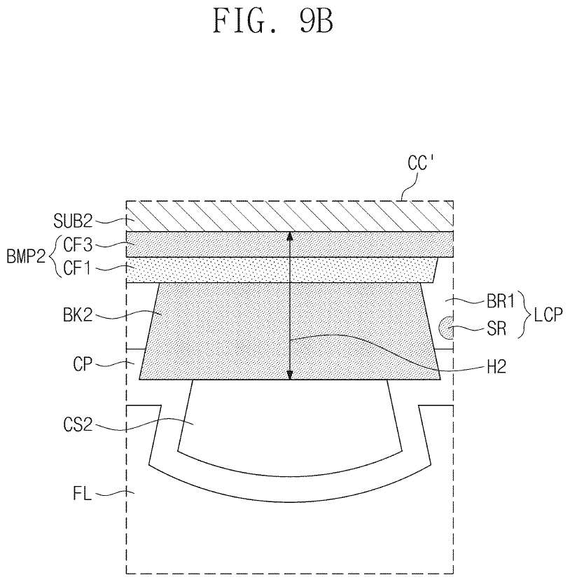

FIG. 8 is a cross-sectional view of the display module taken along the line I-I′ of FIG. 2, according to one or more embodiments of the present disclosure. FIG. 9A is an enlarged view of an area BB′ of FIG. 8, according to one or more embodiments of the present disclosure. FIG. 9B is an enlarged view of an area CC′ of FIG. 8, according to one or more embodiments of the present disclosure. FIG. 8 illustrates a cross-sectional view of the display module DM corresponding to the peripheral area NDA in which the sealing member SAL is arranged and the display area DA adjacent to the peripheral area NDA. In the components illustrated in FIGS. 8 to 9B, descriptions of the same components as the above-described components may not be provided or may only be briefly described with reference to the accompanying drawings.

Referring to FIG. 8, the buffer layer BFL, the first insulating layer INS10, and the second insulating layer INS11 arranged on the top surface of a lower substrate SUB1 may extend from the display area DA toward and/or into the peripheral area NDA. In one or more embodiments, the sealing member SAL may be arranged on the top surface of the second insulating layer INS11 corresponding to the peripheral area NDA. However, the present disclosure is not necessarily limited thereto, and the sealing member SAL may be cut according to the arrangement of the insulating layer of the display panel DP. For example, the sealing member SAL may be arranged on the first insulating layer INS10 or may be in contact with the lower substrate SUB1.

In one or more embodiments, some of the conductive patterns of the circuit layer DP-CL may be arranged between the insulating layers within the peripheral area NDA, and in one or more embodiments, the conductive patterns may overlap the sealing member SAL on the plane (e.g., in a plan view).

The display panel DP may include a plurality of dams DAM1, DAM2, DAM3, and DAM4 arranged on (in) the peripheral area NDA. The plurality of dams DAM1, DAM2, DAM3, and DAM4 may be arranged on the lower substrate SUB1. The dams DAM1, DAM2, DAM3, and DAM4 may be arranged on the second insulation layer INS11.

The dams DAM1, DAM2, DAM3, and DAM4 may include a first dam DAM1, a second dam DAM2, a third dam DAM3, and a fourth dam DAM4, which are arranged to be spaced and/or apart (e.g., spaced apart or separated) from each other along one direction. The first dam DAM may be arranged closest to the display area DA among the dams DAM1, DAM2, DAM3, and DAM4. The fourth dam DAM4 may be arranged furthest away from the display area DA. As an example, the four dams DAM1, DAM2, DAM3, and DAM4 are shown, but the number of dams is not limited thereto.

At least a portion of the dams DAM1, DAM2, DAM3, and DAM4 may have a different laminate structure. For example, the first dam DAM1 may include the same material as the third insulation layer INS12. The second dam DAM2 may include a (1-1)-th film P1-1 and a (1-2)-th film P1-2, which are sequentially laminated along the third direction DR3. The third dam DAM3 may include a (2-1)-th film P2-1 and a (2-2)-th film P2-2, which are sequentially laminated along the third direction DR3. The fourth dam DAM4 may include a (3-1)-th film P3-1 and a (3-2)-th film P3-2, which are sequentially laminated along the third direction DR3. The (1-1)-th film P1-1, the (2-1)-th film P2-1, and the (3-1)-th film P3-1 may include the same material as the third insulating layer INS12, and the (1-2)-th film P1-2, the (2-2)-th film P2-2, and the (3-2)-th film P3-2 may include the same material as the pixel-defining layer PDL.

The first dam DAM1, the (1-1)-th film P1-1, the (2-1)-th film P2-1, and the (3-1)-th film P3-1 may be formed concurrently (e.g., simultaneously) in a process of forming the third insulating layer INS12, and the (1-2)-th film P1-2, the (2-2)-th film P2-2, and the (3-2)-th film P3-2 may be formed concurrently (e.g., simultaneously) in a process of forming the pixel-defining film PDL. However, the present disclosure is not limited thereto, and all the plurality of dams DAM1, DAM2, DAM3, and DAM4 may include the same material.

At least some of the plurality of dams DAM1, DAM2, DAM3, and DAM4 may have different heights in the third direction DR3. For example, the height of the first dam DAM1 may be less than the height of each of the second dam DAM2, the third dam DAM3, and the fourth dam DAM4. However, the present disclosure is not limited thereto, and the heights of the plurality of dams DAM1, DAM2, DAM3, and DAM4 may be the same.

The first encapsulation film EN1 of the encapsulation layer TFE may extend from the display area DA toward and/or into the peripheral area NDA and may be arranged on the plurality of dams DAM1, DAM2, DAM3, and DAM4. The first encapsulation film EN1 of the encapsulation layer TFE may be in contact with the plurality of dams DAM1, DAM2, DAM3, and DAM4. The first encapsulation film EN1 may cover the first dam DAM1, the second dam DAM2, and the third dam DAM3. The first encapsulation film EN1 may cover one side of both sides (e.g., opposite sides) of the fourth dam DAM4 and a portion of a top surface of the fourth dam DAM4. The other side and a portion of a top surface portion (e.g., a portion of the top surface adjacent to the other side) of the fourth dam DAM4 may be exposed to the outside from the first encapsulation film EN1. The one side of the fourth dam DAM4 on which the first encapsulation film EN1 is arranged may be defined as a side adjacent to the display area DA in the first direction DR1 and/or second direction DR2.

The second encapsulation film EN2 of the encapsulation layer TFE may be arranged on the first encapsulation film EN1. A formation area of the second encapsulation film EN2 including the organic film may be partitioned by the dams DAM1, DAM2, DAM3, and DAM4 (e.g., the second encapsulation film EN2 may end at the dams DAM1, DAM2, DAM3, and DAM4). During the manufacturing process of the display panel DP, the second encapsulation film EN2 having fluidity may flow toward the peripheral area NDA and be blocked by one of the dams DAM1, DAM2, DAM3, and DAM4. For example, FIG. 8 illustrates the second encapsulation film EN2 in which a flow of the second encapsulation film EN2 in a space between the first dam DAM1 and the second dam DAM2 is blocked (e.g., in which the second encapsulation film EN2 extends over the first dam DAM1 and ends at the second dam DAM2).

The third encapsulation film EN3 may be arranged on the second encapsulation film EN2 to cover the second encapsulation film EN2. The third encapsulation film EN3 may have a shape corresponding to a top surface of the second encapsulation film EN2. The third encapsulation film EN3 may extend further outward into the peripheral area NDA than the second encapsulation film EN2. The third encapsulation film EN3 may be arranged on the second dam DAM2, which blocks the flow of the second encapsulation film EN2, and may be arranged on the third and fourth dams DAM4 and DAM4, which are arranged outside the second dam DAM2. The third encapsulation film EN3 may be in contact with the first encapsulation film EN1 arranged on the second dam DAM2, the third dam DAM3, and the fourth dam DAM4 and may seal the second encapsulation film EN2 together with the first encapsulation film EN1. Thus, moisture and/or oxygen may be prevented or protected from permeating from the outside into the second encapsulation film EN2, or such permeation may be reduced.

The dams DAM1, DAM2, DAM3, and DAM4 may be spaced and/or apart (e.g., spaced apart or separated) from the sealing member SAL on a plane (e.g., in a plan view). The dams DAM1, DAM2, DAM3, and DAM4 may prevent or reduce the likelihood of the encapsulation layer TFE extending up to the sealing member SAL in the peripheral area NDA.

The bank layer BK may include a first bank layer BK1 and a second bank layer BK2. The first bank layer BK1 may be arranged on (in) the display area DA, and the second bank layer BK2 may be arranged on (in) the peripheral area NDA. In FIG. 8, the first bank layer BK1 and the second bank layer BK2 are illustrated as being spaced and/or apart (e.g., spaced apart or separated) from each other, but in one or more embodiments, the first bank layer BK1 and the second bank layer BK2 may be provided to be integrated with each other. Further, in one or more embodiments, the first bank layer BK1 and the second bank layer BK2 may be integrated with each other in a plan view.

A thickness of the second bank layer BK2 may be greater than a thickness of the first bank layer BK1. A bottom surface of the second bank layer BK2 and a bottom surface of the first bank layer BK1 may be aligned in a line. The bottom surface of the first bank layer BK1 and the bottom surface of the second bank layer BK2 may be defined as surfaces facing (e.g., opposite to) the display panel DP. A difference in thickness of the first bank layer BK1 and thickness of the second bank layer BK2 will be described in more detail in FIGS. 10A and 10B.

The spacer CS may include a first spacer CS1 and a second spacer CS2. The first spacer CS1 may be arranged on (in) the display area DA. The first spacer CS1 may be arranged on the bottom surface of the first bank layer BK1. The second spacer CS2 may be arranged on (in) the peripheral area NDA. The second spacer CS2 may be arranged on the bottom surface of the second bank layer BK2. Thicknesses of the first spacer CS1 and the second spacer CS2 may be the same. However, the present disclosure is not limited thereto, and the thickness of the second spacer CS2 may be less than the thickness of the first spacer CS1. A curvature of an outer surface of the first spacer CS1 may be greater than a curvature of an outer surface of the second spacer CS2.

The display module DM according to one or more embodiments may further include a dummy part DMP. The dummy part DMP may be arranged on (in) the peripheral area NDA. The dummy part DMP may be arranged on a bottom surface of the color filter layer CFL. The dummy part DMP may be covered by the capping layer CP. The dummy part DMP may overlap the sealing member SAL. According to one or more embodiments of the present disclosure, the dummy part DMP may include the same material as the spacer CS. The dummy part DMP may be formed concurrently (e.g., simultaneously) with the spacer CS. The dummy part DMP may include a transparent insulating material.

The dummy part DMP and the capping layer CP may be arranged to extend from the display area DA up to and into the peripheral area NDA. The dummy part DMP and the capping layer CP may be arranged on (in) the display area DA and the peripheral area NDA. The capping layer CP may completely cover the dummy part DMP, the second bank layer BK2, and the second spacer CS2 on (in) the peripheral area NDA. The sealing member SAL may be arranged on a bottom surface of the capping layer CP, which faces the display panel DP on (in) the peripheral area NDA.

FIG. 9A is an enlarged view of a first blocking part BMP1, the first bank layer BK1, and the first spacer CS1, which are arranged on (in) the display area DA, according to one or more embodiments of the present disclosure, and FIG. 9B is an enlarged view of a second blocking part BMP2, the second bank layer BK2, and the second spacer CS2, which are arranged on (in) the peripheral area NDA, according to one or more embodiments of the present disclosure.

Referring to FIGS. 8 to 9b together, the first blocking part BMP1 may be defined on (in) the display area DA, and the second blocking part BMP2 may be defined on (in) the peripheral area NDA. The first blocking part BMP1 may have a structure including the first to third color filters CF1, CF2, and CF3 laminated along the third direction DR3. For example, the first blocking part BMP1 may have a structure in which the first color filter CF1 is arranged under the third color filter CF3, and the second color filter CF2 is arranged under the first color filter CF1. The second blocking part BMP2 may have a structure including the first color filter CF1 and the third color filter CF3 laminated along the third direction DR3. For example, the second blocking part BMP2 may have a structure in which the first color filter CF1 is arranged under the third color filter CF3. For example, the second blocking part BMP2 may have a structure in which the second color filter CF2 is not provided compared to the structure of the first blocking part BMP1. A thickness of the first blocking part BMP1 may be greater than a thickness of the second blocking part BMP2.

The first bank layer BK1 may be arranged under the first blocking member BMP1, and the second bank layer BK2 may be arranged under the second blocking member BMP2. The sum of the thickness of the first bank layer BK1 and the thickness of the first blocking part BMP1 may be defined as a first height H1, and the sum of the thickness of the second bank layer BK2 and the thickness of the second blocking part BMP2 may be defined as a second height H2. The first height H1 may be greater than the second height H2. According to one or more embodiments of the present disclosure, a difference between the first height H1 and the second height H2 may be about 0.1 um or more and about 0.5 um or less. For example, the first height H1 may be about 14.9 um or more and about 15.1 um or less, and the first height H1 may be about 14.3 um or more and about 14.6 um or less.

Because the thickness of the second blocking part BMP2 according to one or more embodiments is less than the thickness of the first blocking part BMP1, it may compensate for the difference between the thickness of the second bank layer BK2 and the thickness of the first bank layer BK1. For example, because the thickness of the second blocking part BMP2 is set to be less than the thickness of the first blocking part BMP1, the second spacer CS2 arranged on the second bank layer BK2 may be arranged to be spaced and/or apart (e.g., spaced apart or separated) from the third encapsulation film EN3 in the third direction DR3.

For example, in one or more embodiments of the present disclosure, a display device includes a display panel with a display area and a peripheral area. A light control layer, including multiple light control parts and a bank layer, is arranged on the display panel. A color filter layer, including a filter part with a single color filter and blocking parts where multiple color filters overlap, is arranged on the light control layer. The bank layer includes a first bank layer in the display area and a second bank layer in the peripheral area. The first blocking part, located in the display area, has three overlapping color filters, while the second blocking part, in the peripheral area, has two overlapping color filters. The thickness of the first blocking part is greater than that of the second blocking part, compensating for differences in the bank layers' thicknesses. Here, FIGS. 9A and 9B illustrate the first blocking part BMP1, the first bank layer BK1, and the first spacer CS1 in the display area DA, and the second blocking part BMP2, the second bank layer BK2, and the second spacer CS2 in the peripheral area NDA. The first height H1, defined by the sum of the first bank layer BK1 and the first blocking part BMP1, is greater than the second height H2, defined by the sum of the second bank layer BK2 and the second blocking part BMP2. The difference between these height ranges from 0.1 μm to 0.5 μm. This design ensures that the second spacer CS2 on the second bank layer BK2 is spaced from the third encapsulation film EN3, maintaining the device's structural integrity.

When the display panel DP and the light control member LCM are bonded to each other, the second spacer CS2 and the third encapsulation film EN3 of the encapsulation layer TFE may not in contact with each other, and thus, the second spacer CS2 and the third encapsulation film EN3 on the peripheral area NDA may be prevented from being in contact with each other or contact may be reduced, thereby preventing or reducing the likelihood of cracks occurring in the third encapsulation film EN3 due to the second spacer CS2. As a result, stains caused by the cracks in the third encapsulation film EN3 may not be visible to the outside, and the display device DD (see, e.g., FIG. 1) having improved display quality may be provided.

FIGS. 10A and 10B are each a cross-sectional view of a display module according to one or more embodiments of the present disclosure. For example, FIGS. 10A and 10B are each a cross-sectional view of a display module, taken along the line I-I′ of FIG. 2, according to one or more embodiments of the present disclosure. In the components illustrated in FIGS. 10A and 10B, descriptions of the same components as the above-described components may not be provided or may only be briefly described with reference to the accompanying drawings.

Referring to FIG. 10A, a display module DMa according to one or more embodiments may further include a low refractive layer LR, a first capping layer CP1, and a second capping layer CP2. The low refractive layer LR, the first capping layer CP1, and the second capping layer CP2 may be configured to be included in the light control member LCM as illustrated, for example, in FIG. 3.

The low refractive index layer LR may be arranged under a color filter layer CFL. The low refractive layer LR may have a refractive index lower than a refractive index of each of the first light conversion layer WCP1, the second light conversion layer WCP2 (see, e.g., FIG. 7), and the light transmission layer LCP. For example, the refractive index of the low refractive layer LR may be about 1.1 or more and about 1.5 or less, and specifically about 1.1 or more and about 1.35 or less. However, the refractive index of the low refractive layer LR is not limited to the above numerical examples. The low refractive layer LR may include a low refractive organic film having a relatively low refractive index. The low refractive layer LR may further include hollow particles and/or voids dispersed within the organic film, and the refractive index of the low refractive layer LR may be controlled or selected by controlling or selecting a ratio of the hollow particles and/or voids.

The low refractive layer LR may use the refractive index to allow light emitted from the top surfaces of the first and second light conversion layers WCP1 and WCP2 (see, e.g., FIG. 7), which was not converted by the first and second light conversion layers WCP1 and WCP2, to be incident again into the first and second light conversion layers WCP1 and WCP2. The light incident again into the first and second light conversion layers WCP1 and WCP2 by the low refractive layer LR may be converted by the quantum dots QD1 and QD2 (see, e.g., FIG. 7). For example, the low refractive index layer LR may improve light output efficiency of the display device DD (see, e.g., FIG. 1) by recirculating the light using the refractive index to send unconverted light back to the first and second light conversion layers WCP1 and WCP2.

The low refractive layer LR layer may include a material having high light transmittance. For example, the low refractive layer LR layer may have high transmittance of more than about 90%. Because the low refractive index layer LR has high transmittance, the transmittance of the light emitted toward the front surface of the display module DM may not be reduced.

The first capping layer CP1 may be arranged on the surface of the low refractive layer LR facing (e.g., opposite to) the display panel DP. The first capping layer CP1 may include an inorganic material. The first capping layer CP1 may prevent or reduce moisture or a gas from being introduced into the low refractive layer LR.

The second capping layer CP2 may be arranged on the bottom surface of each of the bank layers BK1 and BK2 facing (e.g., opposite to) the display panel DP. The second capping layer CP2 may correspond to the capping layer CP illustrated, for example, in FIG. 7. The second capping layer CP2 may cover the bank layers BK1 and BK2, the spacers CS1 and CS2, the light transmission layer LCP, and the first and second light conversion layers WCP1 and WCP2. The second capping layer CP2 may prevent or reduce the likelihood of (e.g., protect from) moisture or foreign substances being introduced into the light transmission layer LCP and the first and second light conversion layers WCP1 and WCP2. The second capping layer CP2 may cover lower portions of the light transmission layer LCP and the first and second light conversion layers WCP1 and WCP2 to protect the light transmission layer LCP and the first and second light conversion layers WCP1 and WCP2 and to prevent or reduce deterioration due to moisture from occurring.

Referring to FIG. 10B, a display module DMb according to one or more embodiments may further include a partition wall SPR, a sub-sealing member SAL-S, and a sub-dummy part DMP-S, which are arranged on (in) the peripheral area NDA.

The partition wall SPR may be arranged on the lower substrate SUB1. The partition wall SPR may include a first layer L1 and a second layer L2, which are sequentially laminated along the third direction DR3. The first layer L1 may include the same material as the third insulating layer INS12, and the second layer L2 may include the same material as the pixel-defining layer PDL.

The sub-sealing member SAL-S may be arranged on the partition wall SPR. The display panel DP and the light control member LCM (see, e.g., FIG. 8) may be more firmly bonded by the sealing member SAL through the sub-sealing member SAL-S. The sub-sealing member SAL-S may include the same material as the sealing member SAL. For example, the sub-sealing member SAL-S may include an ultraviolet curable material.

The sub-dummy part DMP-S may be arranged on the peripheral area NDA. The sub dummy part DMP-S may be arranged on a rear surface of the upper substrate SUB2. The sub-dummy part DMP-S may overlap the sub-sealing member SAL. According to one or more embodiments of the present disclosure, the sub-dummy part DMP-S may include the same material as each of the spacers CS1 and CS2. The sub-dummy part DMP-S may be formed concurrently (e.g., simultaneously) with the spacers CS1 and CS2. The sub-dummy part DMP-S may include a transparent insulating material.

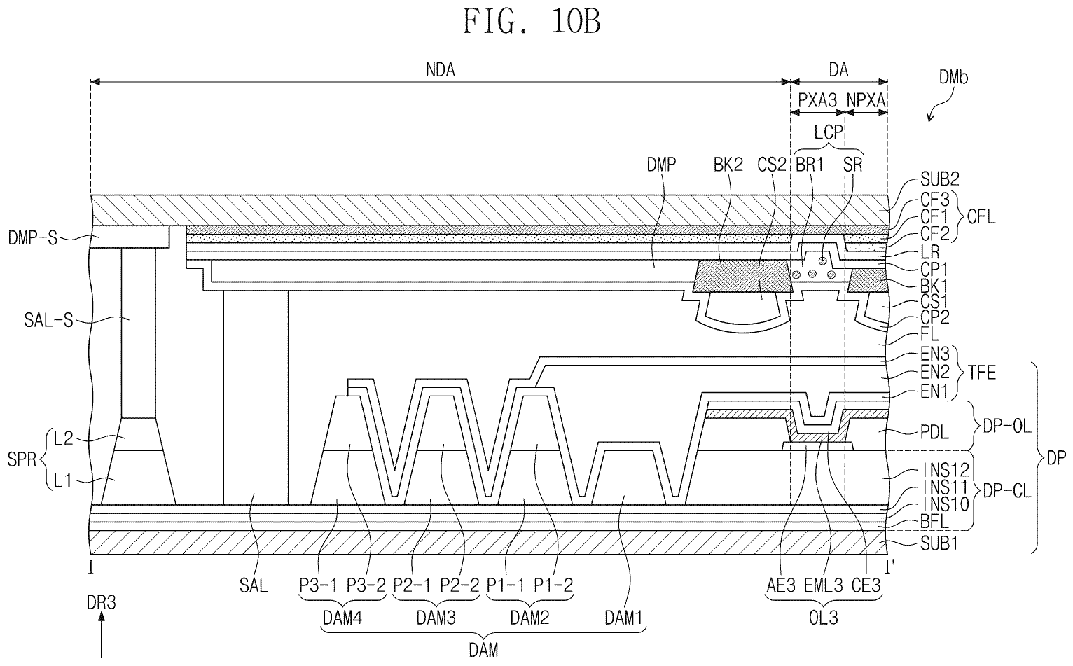

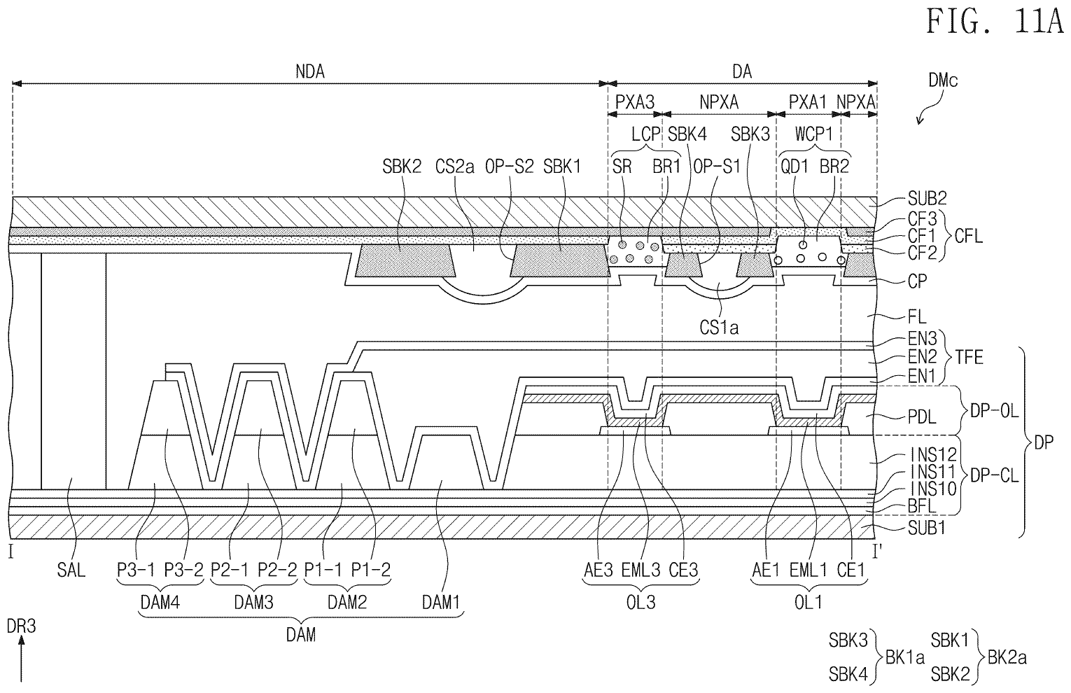

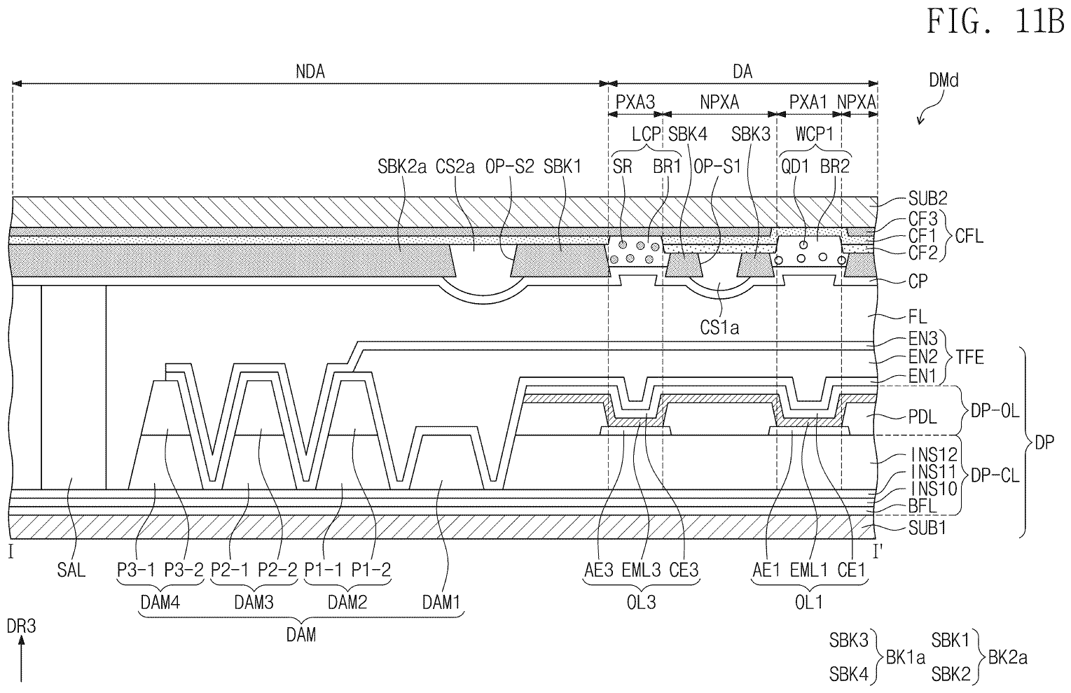

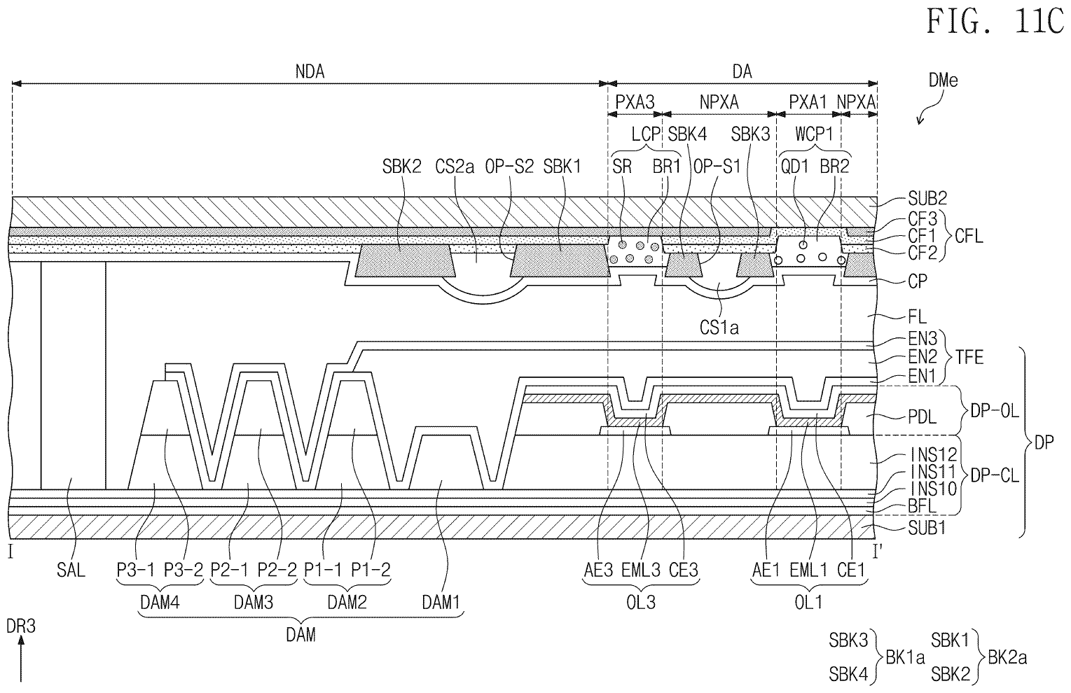

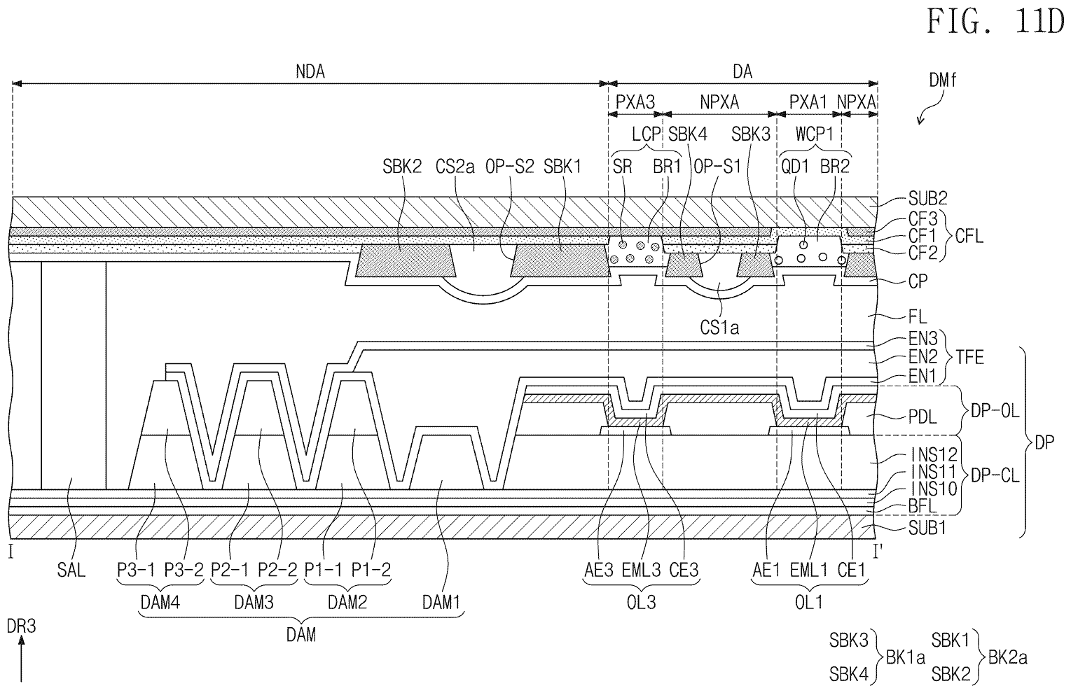

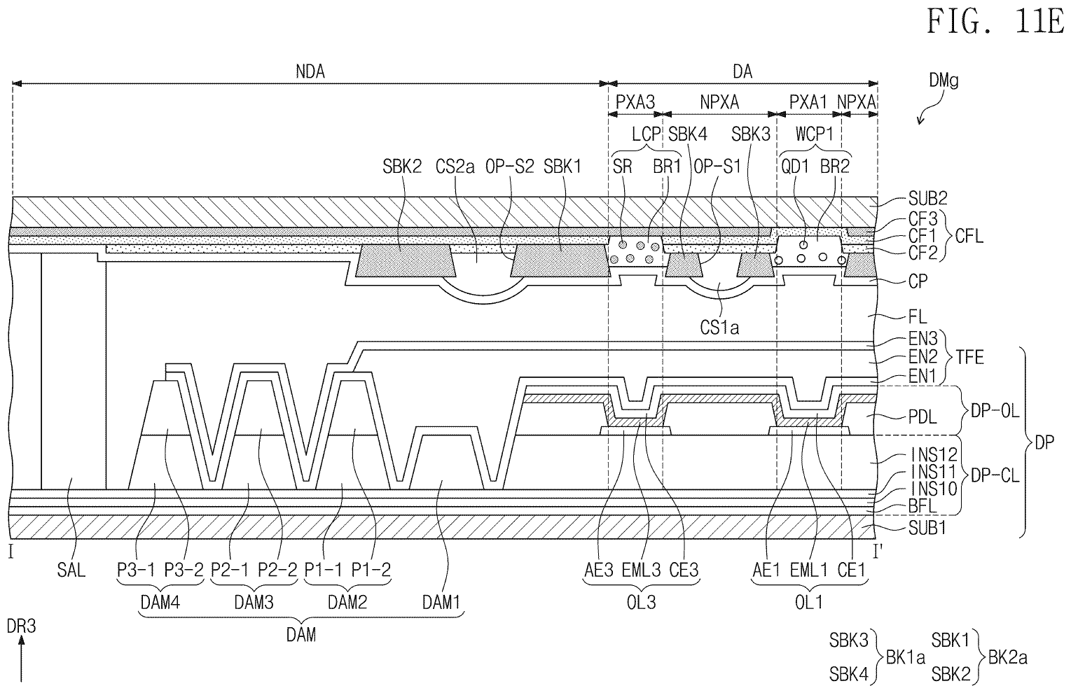

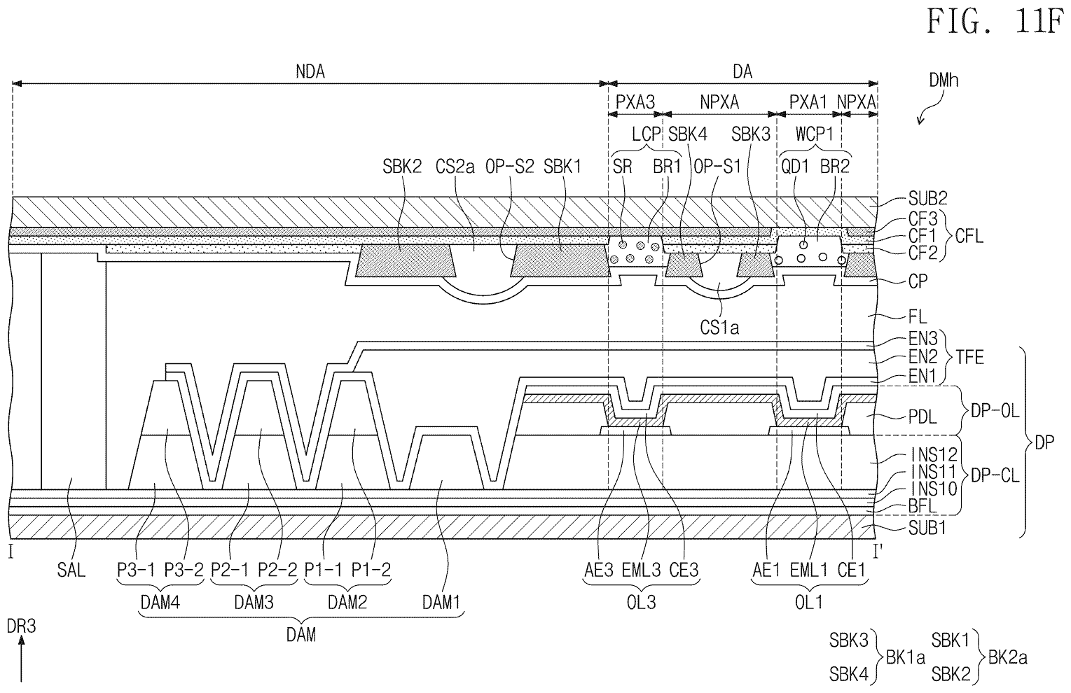

FIG. 11A is a cross-sectional view of a display module DMc according to one or more embodiments of the present disclosure. In FIG. 11A, descriptions of the same components as the above-described components may not be provided or may only be briefly described.

Referring to FIG. 11A, a first bank layer BK1a may be arranged on (in) the display area DA, and a second bank layer BK2a may be arranged on (in) the peripheral area NDA. Each of the first bank layer BK1a and the second bank layer BK2a may be provided as a plurality of bank layers.

The second bank layer BK2a may include a first sub-bank layer SBK1 and a second sub-bank layer SBK2. The first bank layer BK1a may include a third sub-bank layer SBK3 and a fourth sub-bank layer SBK4. A first sub-opening OP-S1 may be defined between the third sub-bank layer SBK3 and the fourth sub-bank layer SBK4, and a second sub-opening OP-S2 may be defined between the first sub-bank layer SBK1 and the second sub-bank layer SBK2. The first sub-opening OP-S1 may be arranged in the display area DA. For example, the first sub-opening OP-S1 may be arranged in the non-emission area NPXA of the display area DA. The first sub-opening OP-S1 may be referred to as a dummy opening.

According to one or more embodiments of the present disclosure, a first spacer CS1a may be arranged in the first sub-opening OP-S1, and a second spacer CS2a may be arranged in the second sub-opening OP-S2. The first spacer CS1a may be arranged on the first blocking part BMP1 (see, e.g., FIG. 9A) in the first sub-opening OP-S1. As illustrated in FIG. 11A, the first spacer CS1a may protrude from the first sub-opening OP-S1, and the second spacer CS2a may protrude from the second sub-opening OP-S2.

Each of the first spacer CS1a and the second spacer CS2a may formed in an inkjet manner. For example, the first spacer CS1a and the second spacer CS2a may be formed by ink being ejected using a nozzle in each of the first sub-opening OP-S1 and the second sub-opening OP-S2. The second spacer CS2a may be arranged to be spaced and/or apart (e.g., spaced apart or separated) from the third encapsulation film EN3 of the encapsulation layer TFE.

FIG. 11B is a cross-sectional view of a display module DMd according to one or more embodiments of the present disclosure. In FIG. 11B, descriptions of the same components as the above-described components may not be provided or may only be briefly described.

Referring to FIG. 11B, a second bank layer BK2b may include a first sub-bank layer SBK1 and a second sub-bank layer SBK2a. The second sub-bank layer SBK2a may extend toward the outside of the peripheral area NDA. The sealing member SAL may overlap the second sub-bank layer SBK2a on the plane (e.g., in a plan view).

FIG. 11C is a cross-sectional view of a display module DMe according to one or more embodiments of the present disclosure. In FIG. 11C, descriptions of the same components as the above-described components may not be provided or may only be briefly described.

Referring to FIG. 11C, a portion of the second color filter CF2 may be arranged on (in) the peripheral area NDA. For example, the second color filter CF2 may be arranged on an entire area on which the first sub-bank layer SBK1 and the second sub-bank layer SBK2 are not arranged. The second color filter CF2 may also be arranged in the second sub-opening OP-S2.

FIG. 11D is a cross-sectional view of a display module DMf according to one or more embodiments of the present disclosure. In FIG. 11D, descriptions of the same components as the above-described components may not be provided or may only be briefly described.

Referring to FIG. 11D, a portion of the second color filter CF2 may be arranged on (in) the peripheral area NDA. However, compared to FIG. 11C, the second color filter CF2 may not be arranged in the second sub-opening OP-S2.

FIG. 11E is a cross-sectional view of a display module DMg according to one or more embodiments of the present disclosure. In FIG. 11E, descriptions of the same components as the above-described components may not be provided or may only be briefly described.

Referring to FIG. 11E, a portion of the second color filter CF2 may be arranged on (in) the peripheral area NDA. The second color filter CF2 may extend toward the outside of the peripheral area NDA, but may not overlap the sealing member SAL. In addition, the second color filter CF2 may be arranged in the second sub-opening OP-S2.

FIG. 11F is a cross-sectional view of a display module DMh according to one or more embodiments of the present disclosure. In FIG. 11F, descriptions of the same components as the above-described components may not be provided or may only be briefly described.

Referring to FIG. 11F, a portion of the second color filter CF2 may be arranged on (in) the peripheral area NDA. The second color filter CF2 may extend toward the outside of the peripheral area NDA, but may not overlap the sealing member SAL. In addition, compared to FIG. 11E, the second color filter CF2 may not be arranged in the second sub-opening OP-S2.

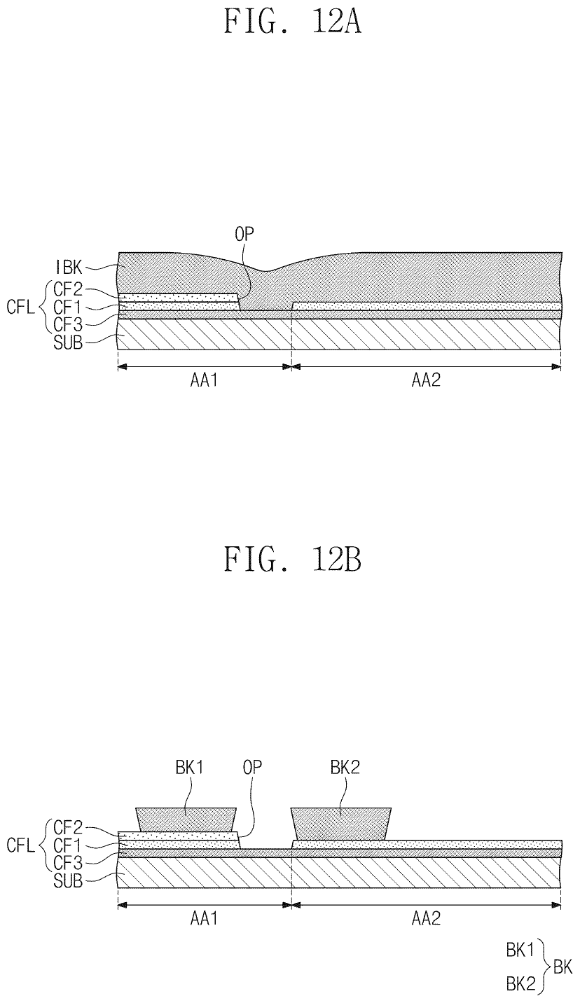

FIGS. 12A and 12B are views for explaining a method for manufacturing first and second bank layers of FIG. 8. In the components illustrated in FIGS. 12A and 12B, descriptions of the same components as the above-described components may not be provided or may only be briefly described with reference to the accompanying drawings.

Referring to FIG. 12A, the base substrate SUB according to one or more embodiments of the present disclosure may correspond to the upper substrate SUB2 illustrated in FIG. 8. The base substrate SUB may be divided into a first area AA1 and a second area AA2. The first area AA1 may correspond to the display area DA illustrated in FIG. 8, and the second area AA2 may correspond to the peripheral area NDA.

A color filter layer CFL may be arranged on the base substrate SUB. An opening OP may be defined by the color filter layer CFL. The opening OP may overlap the first area AA1. The color filter layer CFL may include first to third color filters CF1, CF2, and CF3. In the first area AA1 using the opening OP as a center, the first to third color filters CF1, CF2, and CF3 may be arranged to overlap each other, and in the second area AA2, the first color filter CF1 and the third color filter CF3 may be arranged to overlap each other. For example, the second color filter CF2 may not be arranged on the second area AA2.

A preliminary bank layer IBK may be applied on the color filter layer CFL. The preliminary bank layer IBK may cover the color filter layer CFL. The preliminary bank layer IBK may include a black pigment and a water-repellent material. A portion of the preliminary bank layer IBK adjacent to the opening OP may be recessed more than a portion of the preliminary bank layer IBK spaced and/or apart (e.g., spaced apart or separated) from the opening OP.

In one or more embodiments, a photomask for blocking light may be arranged on the preliminary bank layer IBK. A plurality of openings may be defined in the photomask. The openings may overlap the areas corresponding to the bank layer BK to be formed. A light source may be arranged on the photomask. An exposure process may be performed by light emitted from the light source. The light may pass through the openings and then be irradiated to the preliminary bond layer IBK. A molecular composition or component of the preliminary bank layer IBK, onto which the light is irradiated, may be changed.

After the exposure process is performed, an etching process may be performed. The etching process may be a chemical or physical etching process. The chemical etching process may be a process using a developer. The physical etching process may be a dry or wet etching process.

For example, in one or more embodiments, a photomask for blocking light may be arranged on the preliminary bank layer IBK. A plurality of openings may be defined in the photomask, overlapping the areas corresponding to the bank layer BK to be formed. A light source may be arranged on the photomask, and an exposure process may be performed using light emitted from the light source. The light passes through the openings and irradiates specific areas of the preliminary bank layer IBK, changing its molecular composition or components. After the exposure process, an etching process is performed. This etching process, which can be chemical (using a developer) or physical (dry or wet), removes the non-irradiated parts of the preliminary bank layer, leaving the irradiated parts intact due to their altered molecular composition.

Referring to FIGS. 12A and 12B, a bank layer BK may be formed after the etching process. The bank layer BK may include a first bank layer BK1 and a second bank layer BK2. As the preliminary bank layer IBK adjacent to the opening OP is recessed, a thickness of the first bank layer BK1 may be less than a thickness of the second bank layer BK2. However, the second bank layer BK2 may be arranged on the first color filter CF1 and the third color filter CF3, and thus, this may compensate for a difference between the thickness of the second bank layer BK2 and the thickness of the first bank layer BK1.

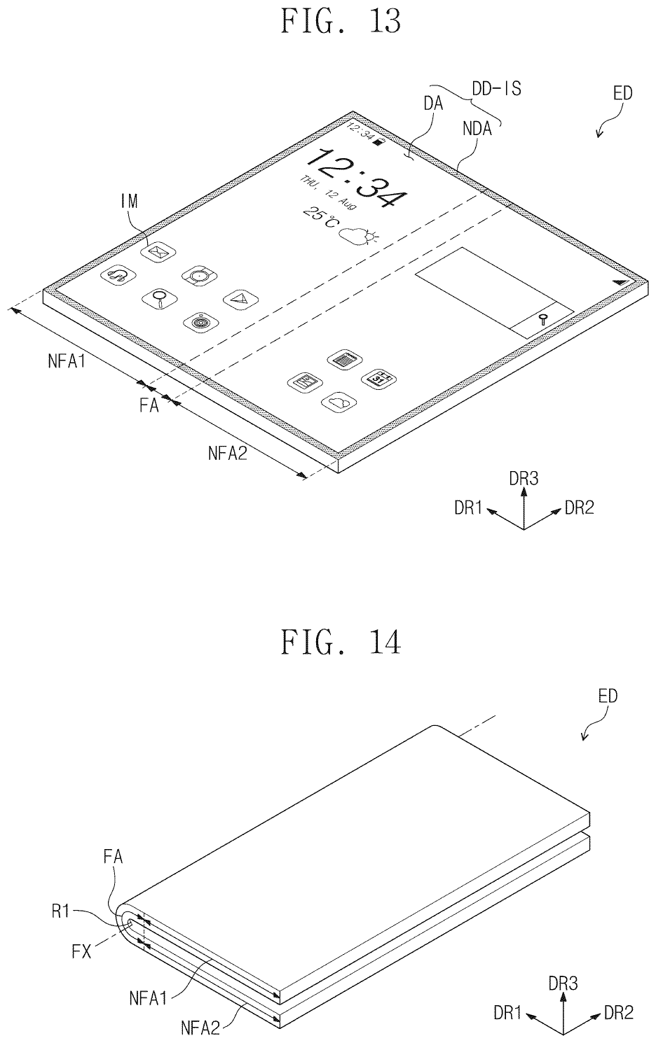

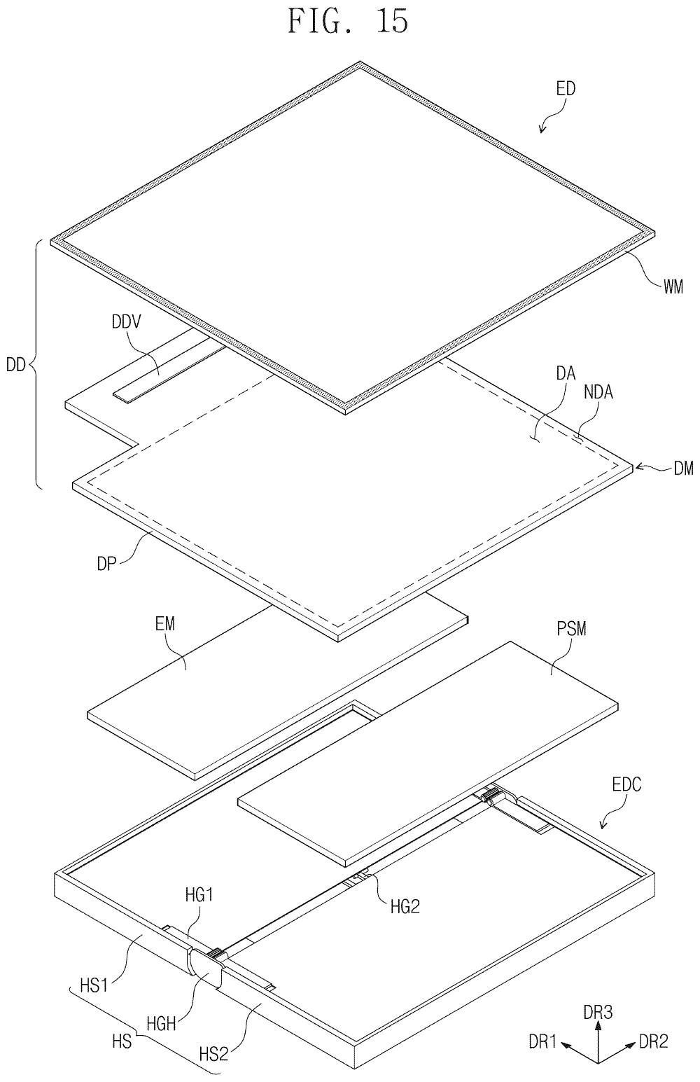

FIG. 13 is a perspective view of an electronic device according to one or more embodiments of the present disclosure. FIG. 14 is a view illustrating a folded state of the electronic device illustrated in FIG. 13, according to one or more embodiments of the present disclosure.

Referring to FIG. 13, an electronic device ED according to one or more embodiments of the present disclosure may have a rectangular shape having short sides extending in a first direction DR1 and long sides extending in a second direction DR2 intersecting the first direction DR1. However, the present disclosure is not limited thereto, and the electronic device ED may have one or more suitable shapes such as a circular shape and/or a polygonal shape. The electronic device ED may be flexible.

The electronic device ED may include a folding area FA and a plurality of non-folding areas NFA1 and NFA2. The non-folding areas NFA1 and NFA2 may include the first non-folding area NFA1 and the second non-folding area NFA2. The folding area FA may be arranged between the first non-folding area NFA1 and the second non-folding area NFA2. The folding area FA, the first non-folding area NFA1, and the second non-folding area NFA2 may be arranged in the first direction DR1.

For example, one folding area FA and two non-folding areas NFA1 and NFA2 are illustrated, but the numbers of folding areas FA and the non-folding areas NFA1 and NFA2 are not limited thereto. For example, the electronic device ED may include more than two non-folding areas and a plurality of folding areas arranged between the non-folding areas.

An upper surface of the electronic device ED may be defined as a display surface DS, and the display surface DS may have the plane defined by the first direction DR1 and the second direction DR2. Images IM generated by the electronic device ED may be provided to a user through the display surface DS.

The display surface DS may include a display area DA and a non-display area NDA around the display area DA. The display area DA displays an image, and the non-display area NDA does not display the image. The non-display area NDA may be around (e.g., surround) the display area DA and may define an edge of the electronic device ED printed in a set or predetermined color.

Referring to FIG. 14, the electronic device ED may be a foldable electronic device ED that is capable of being folded or unfolded. For example, the folding area FA may be bent with respect to a folding axis FX parallel to the second direction DR2, and thus the electronic device ED may be folded. The folding axis FX may be defined as a long axis parallel to the long sides of the electronic device ED. When the electronic device ED is folded, the first non-folding area NFA1 and the second non-folding area NFA2 may face each other, and the electronic device ED may be in-folded so that the display surface DS is not exposed to the outside. However, the present disclosure is not limited thereto. For example, in one or more embodiments, the electronic device ED may be out-folded so that the display surface DS is exposed to the outside about the folding axis FX. Further, in one or more embodiments, the electronic device ED may be in-folded and out-folded at the same time.

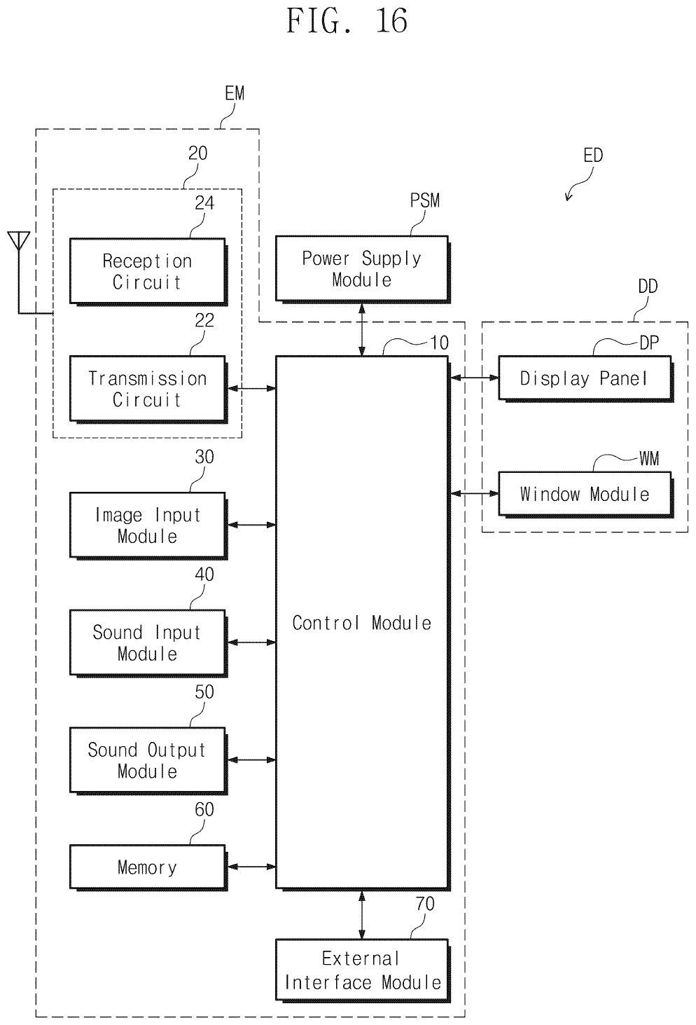

FIG. 15 is an exploded perspective view of the electronic device illustrated in FIG. 13, according to one or more embodiments of the present disclosure.

Referring to FIG. 15, the electronic device ED may include a display device DD, an electronic module EM, a power supply module PSM, and a hinge module EDC. In one or more embodiments, the electronic device ED may further include a mechanical structure (e.g., a hinge) for controlling a folding operation of the display device DD.

The display device DD may generate an image and sense an external input. The display device DD may include a window module WM and a display module DM. The window module WM may provide a front surface of the electronic device ED. The window module WM may be arranged on the display module DM to protect the display module DM. The window module WM may be to transmit a light generated by the display module DM and provide the light to the user.

The display module DM may include a display panel DP. FIG. 15 illustrates the display panel DP among laminated structures of the display module DM, but the display module DM may further include a plurality of components arranged on an upper side and a lower side of the display panel DP. For example, the display panel DP may include a display area DA and a non-display area NDA corresponding to the display area DA and the non-display area NDA of FIG. 13 of the electronic device ED.

The display module DM may include a data driver DDV arranged on the non-display area NDA of the display panel DP. The data driver DDV may be directly manufactured in the form of a circuit chip and mounted on the non-display area NDA. However, the present disclosure is not limited thereto, and the data driver DDV may be mounted on a flexible circuit board connected to the display panel DP.

The electronic module EM and the power supply module PSM may be arranged inside the hinge module EDC. In one or more embodiments, the electronic module EM and the power supply module PSM may be connected to each other through a separate flexible circuit board. The electronic module EM may control an operation of the display device DD. The power supply module PSM may supply power to the electronic module EM.

For example, the electronic module (EM) and the power supply module (PSM) are primarily arranged inside the hinge module (EDC). FIG. 15 illustrates a state in which the EM and PSM are exposed to the outside from the EDC, possibly during maintenance or inspection. In one or more embodiments, the EM and PSM may be connected through a separate flexible circuit board. The EM controls the operation of the display device (DD), while the PSM supplies power to the EM.

The hinge module EDC may accommodate the display device DD, the electronic module EM, and the power supply module PSM. The hinge module EDC may include two first and second housings HS1 and HS2 for folding the display device DD. The first and second housings HS1 and HS2 may extend in the second direction DR2 and may be arranged in the first direction DR1.

The hinge module EDC may include a housing assembly HS. The housing assembly HS may include the first housing HS1 and the second housing HS2 spaced and/or apart (e.g., spaced apart or separated) from each other in the first direction DR1 and a hinge housing HGH arranged between the first housing HS1 and the second housing HS2. The hinge module EDC may further include hinges HG1 and HG2 for connecting the first and second housings HS1 and HS2, a plurality of main plates, and a plurality of moving plates.

FIG. 16 is a block diagram of the electronic device illustrated in FIG. 15, according to one or more embodiments of the present disclosure.

Referring to FIG. 16, the electronic device ED may include the electronic module EM, the power supply module PSM, and the display device DD. The electronic module EM may include a control module 10, a wireless communication module 20, an image input module 30, a sound input module 40, a sound output module 50, a memory 60, an external interface module 70, and/or the like. The modules may be mounted on a circuit board or may be electrically connected through a flexible circuit board. The electronic module EM may be electrically connected to the power supply module PSM.

The control module 10 may control an overall operation of the electronic device ED. For example, the control module 10 may activate or deactivate the display device DD in accordance with a user input. The control module 10 may control the image input module 30, the sound input module 40, the sound output module 50, and/or the like, in accordance with the user input. The control module 10 may include at least one microprocessor.

The wireless communication module 20 may be to transmit/receive a wireless signal to/from another terminal using Bluetooth or Wi-Fi. The wireless communication module 20 may be to transmit/receive a voice signal using a general communication line. The wireless communication module 20 may include a transmission circuit 22 for modulating and transmitting a signal to be transmitted, and a reception circuit 24 for demodulating a received signal.

The image input module 30 may process an image signal and convert the image signal into image data that may be displayed on the display device DD. The sound input module 40 may receive an external sound signal through a microphone in a recording mode or a voice recognition mode and convert the received external sound signal into electrical voice data. The sound output module 50 may convert sound data received from the wireless communication module 20 or sound data stored in the memory 60 and output the converted sound data to the outside.

The external interface module 70 may serve as an interface connected to an external charger, a wired/wireless data port, and/or a card socket (e.g., a memory card, and/or a subscriber identity module (SIM)/user interface model (UIM) card).

The power supply module PSM may supply power for an overall operation of the electronic device ED. The power supply module PSM may include a general battery device.

The thickness of the second blocking part arranged on the peripheral area according to one or more embodiments of the present disclosure may be less than the thickness of the first blocking part arranged on the display area so that the spacer arranged on the peripheral area is spaced and/or apart (e.g., spaced apart or separated) from the encapsulation layer. As a result, when bonding the display panel to the light control member, the spacer and the encapsulation layer may be prevented from being in contact with each other (or contact between the spacer and the encapsulation layer may be reduced) in order to prevent or reduce cracks that may occur in the encapsulation layer that are generated due to contact with the spacer.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The display device, electronic apparatus, device for manufacturing the display device, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a display panel comprising a display area and a peripheral area adjacent to the display area;
a light control layer on the display panel and comprising a plurality of light control parts and a bank layer between the plurality of light control parts; and
a color filter layer on the light control layers and comprising a filter part in which a single color filter is arranged, and a blocking part in which at least two or more color filters overlap,
wherein the bank layer comprises:
a first bank layer on the display area and on a first blocking part of the blocking part where three color filters overlap in the first blocking part; and
a second bank layer on the peripheral area and on a second blocking part of the blocking part, where two color filters overlap in the second blocking part.

2. The display device of claim 1, wherein the color filter layer comprises:
a first color filter through which first color light is to be transmitted;
a second color filter through which second color light is to be transmitted; and
a third color filter through which third color light is to be transmitted.

3. The display device of claim 2, wherein the first blocking part has a structure in which the first to third color filters are laminated, and
the second blocking part has a structure in which the first color filter and the third color filter are laminated.

4. The display device of claim 3, wherein a sum of a thickness of the first bank layer and a thickness of the first blocking part is defined as a first height, and a sum of a thickness of the second bank layer and a thickness of the second blocking part is defined as a second height, and
wherein the first height is greater than the second height.

5. The display device of claim 4, wherein a difference between the first height and the second height is about 0.1 um or more and about 0.5 um or less.

6. The display device of claim 2, wherein the first color filter comprises a first pigment,
the second color filter comprises a second pigment, and
the third color filter comprises a third pigment.

7. The display device of claim 6, wherein each of the first to third color filters further comprises a scatterer.

8. The display device of claim 1, wherein the display panel further comprises a plurality of light emitting elements to emit first color light, and
the display device is divided into a first pixel area, which is to emit second color light different from the first color light, a second pixel area, which is to emit third color light different from each of the first color light and the second color light, and a third pixel area, which is to emit the first color light.

9. The display device of claim 8, wherein the plurality of light control parts comprise:
a first light control part overlapping the first pixel area and to convert the first color light into the second color light;
a second light control part overlapping the second pixel area and to convert the first color light into the third color light; and
a third light control part overlapping the third pixel area and to transmit the first color light therethrough.

10. The display device of claim 8, wherein
the display panel further comprises an encapsulation layer to cover the plurality of light emitting elements, and
the encapsulation layer and each of the first and second bank layers are spaced from each other.

11. The display device of claim 10, further comprising a plurality of spacers on the color filter layer that faces the display panel,
wherein the encapsulation layer and each of the plurality of spacers are spaced from each other.

12. The display device of claim 11, wherein the plurality of spacers are on a bottom surface of the first bank layer and a bottom surface of the second bank layer, and
wherein the bottom surface of the first bank layer and the bottom surface of the second bank layer each face the display panel.

13. The display device of claim 11, wherein openings are defined in the first bank layer and the second bank layer, respectively,
wherein the plurality of spacers are in the openings of the first bank layer and the second bank layer.

14. A display device comprising:
a display panel comprising a display area and a peripheral area adjacent to the display area;
a color filter layer comprising a filter part in which a single color filter is arranged, and a blocking part in which at least two or more color filters overlap; and
a light control layer between the display panel and the color filter layer and comprising a plurality of light control parts and a bank layer between the plurality of light control parts,
wherein the bank layer comprises:
a first bank layer on the display area, and
a second bank layer on the peripheral area,
wherein a sum of a thickness of the first bank layer and a thickness of the blocking part is less than that of a thickness of the second bank layer and the thickness of the blocking part.

15. The display device of claim 14, wherein the color filter layer comprises:
a first color filter through which first color light is to be transmitted;
a second color filter through which second color light is to be transmitted; and
a third color filter through which third color light is to be transmitted.

16. The display device of claim 15, wherein the blocking part comprises:
a first blocking part on the display area and having a structure in which the first to third color filters are laminated; and
a second blocking part on the peripheral area and having a structure in which the first color filter and the third color filter are laminated.

17. The display device of claim 16, wherein a sum of the thickness of the first bank layer and a thickness of the first blocking part is defined as a first height, and
a sum of the thickness of the second bank layer and a thickness of the second blocking part is defined as a second height, and
wherein a different between the first height and the second height is about 0.1 um or more and about 0.5 um or less.

18. The display device of claim 14, wherein the display panel further comprises:
a plurality of light emitting elements to emit first color light; and
an encapsulation layer to cover the plurality of light emitting elements, and
wherein the encapsulation layer and each of the first and second bank layers are spaced from each other.

19. The display device of claim 18, further comprising a plurality of spacers on a bottom surface of the first bank layer and a bottom surface of the second bank layer, respectively,
wherein the bottom surface of the first bank layer and the bottom surface of the second bank layer each face the display panel, and
wherein the encapsulation layer and each of the plurality of spacers are spaced from each other.

20. An electronic device comprising:
a display device;
an electronic module overlapping the display device; and
a housing accommodating the display device,
wherein the display device comprises:
a display panel comprising a display area and a peripheral area adjacent to the display area;
a light control layer on the display panel and comprising a plurality of light control parts and a bank layer between the plurality of light control parts; and
a color filter layer on the light control layers and comprising a filter part in which a single color filter is arranged, and a blocking part in which at least two or more color filters overlap,
wherein the bank layer comprises:
a first bank layer on the display area and on a first blocking part of the blocking part, where three color filters overlap in the first blocking part; and
a second bank layer on the peripheral area and on a second blocking part of the blocking part, where two color filters overlap in the second blocking part.
